(19) United States
(12) Patent Application Publication
(10) Pub. No.: US 2025/0015177 A1
(43) Pub. Date: Jan. 9, 2025

(54) SEMICONDUCTOR DEVICE

(71) Applicant: ROHM CO., LTD., Kyoto (JP)

(72) Inventor: Yuki NAKANO, Kyoto (JP)

(73) Assignee: ROHM CO., LTD., Kyoto (JP)

(21) Appl. No.: 18/895,430

(22) Filed: Sep. 25, 2024

Related U.S. Application Data
(63) Continuation of application No. PCT/JP2023/006634, filed on Feb. 24, 2023.

(30) Foreign Application Priority Data
Mar. 31, 2022 (JP) 2022-061171

(51) Int. Cl. H01L 29/78; H01L 29/06; H01L 29/10; H01L 29/872

(52) U.S. Cl. CPC H01L 29/7813; H01L 29/1095; H01L 29/7806; H01L 29/872; H01L 29/0603

(57) ABSTRACT

A semiconductor device includes a chip having a first main surface which serves as a device surface and a second main surface which serves as a non-device surface, and a first conductivity type drift gradient region formed in the chip, and having a concentration profile in which an impurity concentration of an end portion on the first main surface side is lower than an impurity concentration of an end portion on the second main surface side.

### CROSS-REFERENCE TO RELATED APPLICATIONS

The present application is a bypass continuation of International Patent Application No. PCT/JP2023/006634, filed on Feb. 24, 2023, which claims priority to Japanese Patent Application No. 2022-061171 filed on Mar. 31, 2022, the entire disclosures of those applications are incorporated herein by reference.

### BACKGROUND

### 1. Field of the Disclosure

The present disclosure relates to a semiconductor device.

### 2. Description of the Related Art

JP2006245475A discloses a semiconductor device including a drift layer. The drift layer includes a first region, a second region, and a third region. The first region has a first impurity concentration n1, the second region has a second impurity concentration n2, and a third region has a third impurity concentration n3. The first to third impurity concentrations n1 to n3 are set to be values under a condition of “n2<n1<n3” in consideration of a cosmic ray tolerance.

### BRIEF DESCRIPTION OF THE DRAWINGS

FIG. 1 is a plan view illustrating a semiconductor device according to a first embodiment.

FIG. 2 is a cross-sectional view taken along line II-II illustrated in FIG. 1.

FIG. 3A is a diagram for describing a concentration distribution in a chip together with a drift gradient region according to a first embodiment example.

FIG. 3B is a diagram for describing the concentration distribution in the chip together with a drift gradient region according to a second embodiment example.

FIG. 4 is a plan view illustrating a semiconductor device according to a second embodiment.

FIG. 5 is a cross-sectional view taken along line V-V illustrated in FIG. 4.

FIG. 6A is a diagram for describing a concentration distribution in a chip together with a drift gradient region according to a first embodiment example.

FIG. 6B is a diagram for describing a concentration distribution in the chip together with a drift gradient region according to a second embodiment example.

FIG. 7 is a plan view illustrating major parts of the semiconductor device illustrated in FIG. 3.

FIG. 8 is a cross-sectional view taken along line VIII-VIII illustrated in FIG. 7.

FIG. 9 is an enlarged cross-sectional view illustrating a peripheral edge portion of the chip.

FIG. 10 is a cross-sectional view corresponding to FIG. 2 and illustrating a modified example of the chip.

FIG. 11 is a cross-sectional view corresponding to FIG. 2 and illustrating a modified example of the chip.

FIG. 12 is a diagram corresponding to FIG. 3A and illustrating a modified example of the chip.

### DETAILED DESCRIPTION OF THE PREFERRED EMBODIMENTS

Hereinafter, embodiments will be described in detail with reference to the attached drawings. The attached drawings are schematic views and are not strictly illustrated. Scales, etc., do not always match. Also, corresponding structures between the attached drawings will be given the same reference signs, and duplicated description will be omitted or simplified. Regarding the structures whose description is omitted or simplified, the description made before omission or simplification is applied.

In a case where the phrase “substantially equal” is used in a description with a comparison target, this phrase not only includes a numeric value (embodiment) equal to a numeric value (embodiment) of the comparison target, and also includes a numerical error (embodiment error) within a range of ±10% based on the numeric value (embodiment) of the comparison target. In the embodiments, terms such as “first,” “second,” and “third” will be used. However, these are signs attached to names of structures for clarifying the order of description and not attached for the purpose of limiting the names of the structures.

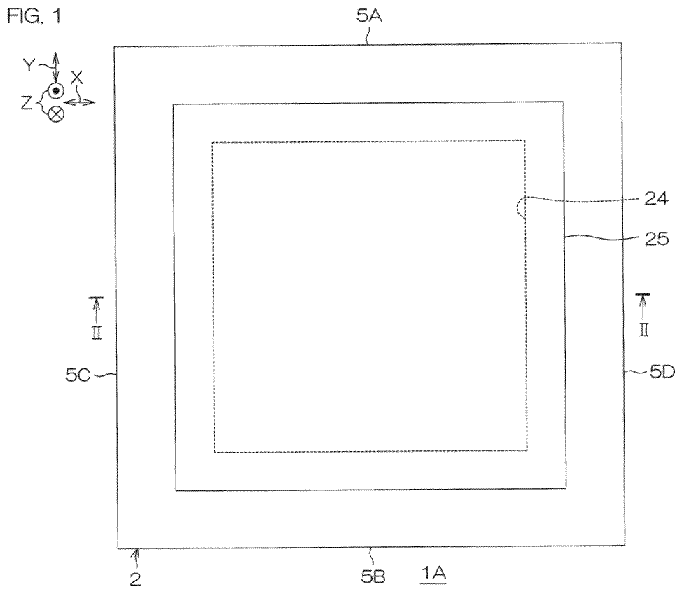

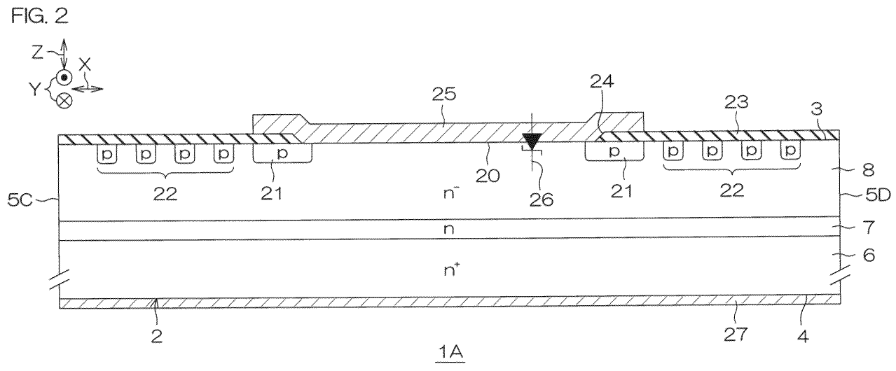

FIG. 1 is a plan view illustrating a semiconductor device 1A according to a first embodiment. FIG. 2 is a cross-sectional view taken along line II-II illustrated in FIG. 1. With reference to FIGS. 1 and 2, in this embodiment, the semiconductor device 1A includes a chip 2 including a single crystal of a wide-bandgap semiconductor, the chip being formed in a hexagonal shape (specifically, in a rectangular parallelepiped shape). That is, the semiconductor device 1A is a “wide-bandgap semiconductor device.”

The chip 2 may also be called as a “semiconductor chip” or a “wide-bandgap semiconductor chip.” The wide-bandgap semiconductor is a semiconductor having a bandgap exceeding a bandgap of Si (silicon). GaN (gallium nitride), SiC (silicon carbide), and C (diamond) are exemplified as the wide-bandgap semiconductor.

In this embodiment, the chip 2 is an “SiC chip” including a hexagonal SiC single crystal, which serves as an example of the wide-bandgap semiconductor. That is, the semiconductor device 1A is an “SiC semiconductor device.” The hexagonal SiC single crystal has a plurality of polytypes including a 2H(Hexagonal)-SiC single crystal, a 4H-SiC single crystal, and a 6H-SiC single crystal, etc. In this embodiment, an example in which the chip 2 includes the 4H-SiC single crystal is shown. However, the chip 2 may be made of the other polytypes.

The chip 2 has a first main surface 3 on one side, a second main surface 4 on the other side, and first to fourth side surfaces 5A to 5D that connect the first main surface 3 and the second main surface 4. The first main surface 3 is a device surface in which major structures of a functional device are formed. The second main surface 4 is a non-device surface on the opposite side to the first main surface 3. The first main surface 3 and the second main surface 4 are formed in a square shape in a plan view seen from the normal direction Z of the main surfaces (hereinafter, simply referred to as “in a plan view”). The normal direction Z is also the thickness direction of the chip 2. The first main surface 3 and the second main surface 4 are preferably formed by a c-plane of an SiC single crystal.

In this case, preferably, the first main surface 3 is formed by a silicon plane of an SiC single crystal, and the second main surface 4 is formed by a carbon plane of an SiC single crystal. The first main surface 3 and the second main surface 4 may have an off angle inclined by a predetermined angle in the predetermined off direction with respect to the c-plane. The off direction is preferably the a-axis direction ([11-20] direction) of the SiC single crystal. The off angle may exceed 0° and may be not more than 10°. The off angle is preferably not more than 5°. The second main surface 4 may be formed by a grinding surface having a grinding mark or may be formed by a smooth surface having no grinding mark.

The first side surface 5A and the second side surface 5B extend in the first direction X along the first main surface 3, and oppose each other in the second direction Y crossing (specifically, orthogonal to) the first direction X. The third side surface 5C and the fourth side surface 5D extend in the second direction Y and oppose each other in the first direction X. The first direction X may be the m-axis direction ([1-100] direction) of the SiC single crystal, and the second direction Y may be the a-axis direction of the SiC single crystal. As a matter of course, the first direction X may be the a-axis direction of the SiC single crystal, and the second direction Y may be the m-axis direction of the SiC single crystal. The first to fourth side surfaces 5A to 5D may be formed by a grinding surface having a grinding mark or may be formed by a smooth surface having no grinding mark.

The chip 2 may have a thickness of not less than 5 μm and not more than 200 μm. The thickness of the chip 2 may be set to be a value that belongs to any one of ranges including not less than 5 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, and not less than 175 μm and not more than 200 μm. The thickness of the chip 2 is preferably not more than 100 μm.

The first to fourth side surfaces 5A to 5D may have a length of not less than 0.5 mm and not more than 20 mm in a plan view. The length of the first to fourth side surfaces 5A to 5D may be set to be a value that belongs to any one of ranges including not less than 0.5 mm and not more than 5 mm, not less than 5 mm and not more than 10 mm, not less than 10 mm and not more than 15 mm, and not less than 15 mm and not more than 20 mm. The length of the first to fourth side surfaces 5A to 5D is preferably not less than 5 mm.

The semiconductor device 1A includes an n-type (first conductivity type) base region 6 formed in a region on the second main surface 4 side inside the chip 2. The base region 6 is formed in a layer shape extending along the second main surface 4, and exposed from the second main surface 4 and the first to fourth side surfaces 5A to 5D. In this embodiment, the base region 6 is exposed from the entire region of the second main surface 4. That is, the base region 6 forms the second main surface 4. In this embodiment, the base region 6 is made of an SiC substrate (semiconductor substrate).

The base region 6 may have a thickness of not less than 1 μm and not more than 200 μm. The thickness of the base region 6 may be not more than 150 μm, not more than 100 μm, not more than 50 μm, or not more than 40 μm. The thickness of the base region 6 may be not less than 5 μm. The thickness of the base region 6 is preferably not less than 10 μm. By reducing the thickness of the base region 6, it is possible to reduce a resistance value due to the base region 6 in the chip 2.

The semiconductor device 1A includes an n-type buffer region 7 formed in a region on the first main surface 3 side with respect to the base region 6 inside the chip 2. The buffer region 7 is formed in a layer shape extending along the base region 6 so that the buffer region 7 is connected to the base region 6, and exposed from the first to fourth side surfaces 5A to 5D.

In this embodiment, the buffer region 7 is formed by an epitaxial layer (specifically, an SiC epitaxial layer) laminated on the base region 6 (SiC substrate). The buffer region 7 may have a thickness of not less than 0.1 μm and not more than 5 μm. The thickness of the buffer region 7 is preferably not less than 1 μm and not more than 3 μm.

The semiconductor device 1A includes an n-type drift gradient region 8 formed in a region on the first main surface 3 side with respect to the buffer region 7 inside the chip 2. The drift gradient region 8 may also be called as a “drift region.” The drift gradient region 8 is formed in a layer shape extending along the base region 6 so that the drift gradient region 8 is connected to the buffer region 7, and exposed from the first main surface 3 and the first to fourth side surfaces 5A to 5D. In this embodiment, the drift gradient region 8 is exposed from the entire region of the first main surface 3. That is, the drift gradient region 8 forms the first main surface 3.

In this embodiment, the drift gradient region 8 is formed by an epitaxial layer (specifically, an SiC epitaxial layer) laminated on the buffer region 7 (epitaxial layer). The drift gradient region 8 is preferably thicker than the buffer region 7. The drift gradient region 8 may have a thickness of not less than 1 μm and not more than 50 μm. The thickness of the drift gradient region 8 is preferably not less than 3 μm and not more than 30 μm. The thickness of the drift gradient region 8 is particularly preferably not more than 25 μm.

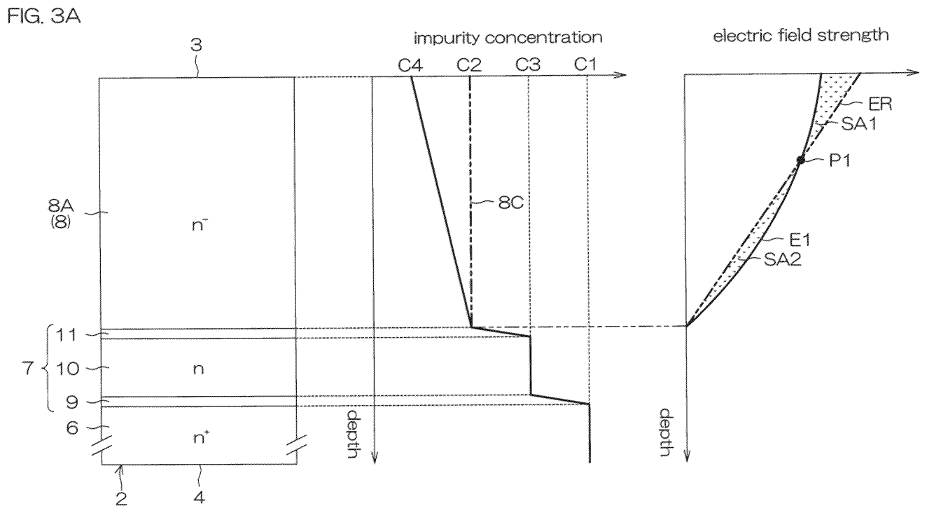

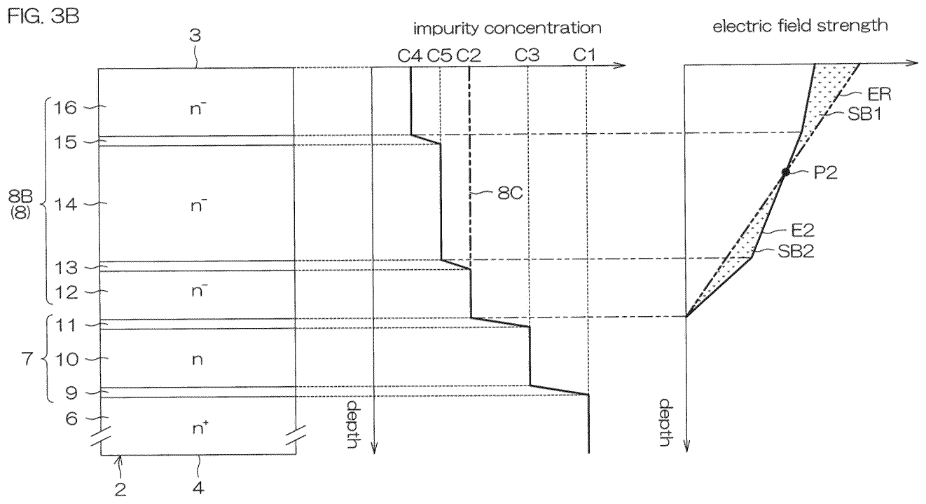

Hereinafter, with reference to FIGS. 3A and 3B, specific configurations of the base region 6, the buffer region 7, and the drift gradient region 8 will be described. FIG. 3A is a diagram for describing a concentration distribution in the chip 2 together with the drift gradient region 8 according to a first embodiment example (hereinafter, referred to as the “drift gradient region 8A”). FIG. 3B is a diagram for describing the concentration distribution in the chip 2 together with the drift gradient region 8 according to a second embodiment example (hereinafter, referred to as the “drift gradient region 8B”).

With reference to FIGS. 3A and 3B, the base region 6 has an n-type first concentration C1. The first concentration C1 may also be called as the “base concentration.” The first concentration C1 is adjusted to be a substantially fixed value from the second main surface 4 side toward the first main surface 3 side. The first concentration C1 may be set within a range of not less than 1×10¹⁸ cm⁻³ and not more than 1×10²¹ cm⁻³. The first concentration C1 is preferably set within a range of not less than 1×10¹⁸ cm⁻³ and not more than 1×10¹⁹ cm⁻³.

The buffer region 7 has an impurity concentration lower than an impurity concentration of the base region 6. The n-type impurity concentration of the buffer region 7 may be set within a range of not less than 1×10¹⁶ cm⁻³ and not more than 1×10²⁰ cm⁻³. The n-type impurity concentration of the buffer region 7 is preferably set within a range of not less than 1×10¹⁷ cm⁻³ and not more than 1×10¹⁹ cm⁻³. In this embodiment, the buffer region 7 has a concentration profile in which the impurity concentration is lowered from the first concentration C1 to a second concentration C2 which is less than the first concentration C1 toward the first main surface 3 side. The second concentration C2 may also be called as the “buffer concentration.”

In this embodiment, the buffer region 7 includes a first transition region 9, a holding region 10, and a second transition region 11 formed in this order from the base region 6 side. The first transition region 9 has a concentration profile in which an impurity concentration is gradually reduced from the first concentration C1 to a third concentration C3 which is less than the first concentration C1 from the base region 6 toward the first main surface 3 side.

The third concentration C3 may also be called as the “intermediate buffer concentration.” The holding region 10 has the third concentration C3 which is substantially fixed from the first transition region 9 toward the first main surface 3 side. The second transition region 11 has a concentration profile in which an impurity concentration is gradually reduced from the third concentration C3 to the second concentration C2 which is less than the third concentration C3 from the holding region 10 toward the first main surface 3 side.

The drift gradient region 8 has a concentration profile in which an impurity concentration of an end portion on the first main surface 3 side is lower than an impurity concentration of an end portion on the second main surface 4 side. The drift gradient region 8 has an n-type impurity concentration lower than the base region 6. Specifically, the drift gradient region 8 has the n-type impurity concentration lower than the buffer region 7. The n-type impurity concentration of the drift gradient region 8 may be set within a range of not less than 1×10¹⁴ cm⁻³ and not more than 1×10¹⁷ cm⁻³. The n-type impurity concentration of the drift gradient region 8 is preferably set within a range of not less than 1×10¹⁵ cm⁻³ and not more than 1×10¹⁷ cm⁻³.

With reference to FIG. 3A, the semiconductor device 1A may include the n-type drift gradient region 8A according to the first embodiment example as an example of the drift gradient region 8. The drift gradient region 8A has a concentration profile in which an n-type impurity concentration is gradually lowered from the buffer region 7 side (second main surface 4 side) toward the first main surface 3 side in the chip 2. Specifically, the n-type impurity concentration is lowered from the second concentration C2 to a fourth concentration C4 which is less than the second concentration C2 from the buffer region 7 side toward the first main surface 3 side. The fourth concentration C4 may also be called as the “drift concentration.”

The n-type impurity concentration is lowered in a downward inclining manner at a fixed rate from the second concentration C2 to the fourth concentration C4. That is, in this embodiment example, the n-type impurity concentration is gradually reduced from the second concentration C2 to the fourth concentration C4 in a straight line manner (primary straight line manner).

The drift gradient region 8A is configured to form a first electric field distribution E1 in the chip 2. The first electric field distribution E1 has a profile in which an electric field strength is monotonically increased from the buffer region 7 side toward the first main surface 3 side. That is, the first electric field distribution E1 has a maximum electric field strength in an end portion on the first main surface 3 side and has a minimum electric field strength in an end portion on the buffer region 7 side.

In the first electric field distribution E1, an increase ratio of the electric field strength on the first main surface 3 side is smaller than an increase ratio of the electric field strength on the buffer region 7 side. Also, the increase ratio of the electric field strength is gradually reduced from the buffer region 7 side toward the first main surface 3 side. Therefore, the first electric field distribution E1 is gradually increased in a curved line manner (secondary curved line manner) from the buffer region 7 side toward the first main surface 3 side.

FIG. 3A illustrates a concentration profile of a drift region 8C according to a reference example (see a double chain line). The drift region 8C according to the reference example is formed to have the second concentration C2 which is fixed from the buffer region 7 side toward the first main surface 3 side. The drift region 8C according to the reference example forms a reference electric field distribution ER in the chip 2. The reference electric field distribution ER has a profile in which an electric field strength is monotonically increased at a fixed rate from the buffer region 7 side toward the first main surface 3 side.

The reference electric field distribution ER has a maximum electric field strength in an end portion on the first main surface 3 side and has a minimum electric field strength in an end portion on the buffer region 7 side. The maximum electric field strength of the reference electric field distribution ER is higher than the maximum electric field strength of the first electric field distribution E1. The minimum electric field strength of the reference electric field distribution ER is substantially equal to the minimum electric field strength of the first electric field distribution E1. The reference electric field distribution ER has a first intersection point P1 crossing the first electric field distribution E1 in an intermediate portion of a thickness range of the drift region 8C (drift gradient region 8).

A first area SA1 is formed in a range of not less than the first electric field distribution E1 and not more than the reference electric field distribution ER in a thickness range between the first main surface 3 and the first intersection point P1. A second area SA2 is formed in a range of not less than the reference electric field distribution ER and not more than the first electric field distribution E1 in a thickness range between the buffer region 7 and the first intersection point P1.

In this case, the second area SA2 is preferably adjusted to be substantially equal to the first area SA1. According to this structure, a breakdown voltage in a case where the drift gradient region 8A according to the first embodiment example is formed is substantially equal to a breakdown voltage in a case where the drift region 8C according to the reference example is formed.

With reference to FIG. 3B, the semiconductor device 1A may include the n-type drift gradient region 8B according to the second embodiment example as an example of the drift gradient region 8. The drift gradient region 8B has a concentration profile in which an n-type impurity concentration is gradually lowered from the buffer region 7 side (second main surface 4 side) toward the first main surface 3 side in the chip 2. Specifically, the n-type impurity concentration is lowered from the second concentration C2 to the fourth concentration C4 which is less than the second concentration C2 from the buffer region 7 toward the first main surface 3.

In this embodiment example, the n-type impurity concentration is lowered stepwise. That is, the n-type impurity concentration is lowered in a downward staircase manner from the second concentration C2 to the fourth concentration C4. The n-type impurity concentration may be lowered in a one-step staircase manner or may be lowered in a multi-step staircase manner of two or more steps. The number of downward steps of the n-type impurity concentration is arbitrary. Therefore, the n-type impurity concentration may be lowered in a multi-step staircase manner of four or more steps.

In this embodiment example, the drift gradient region 8B has a configuration that the n-type impurity concentration is lowered in a three-step staircase manner. Specifically, the drift gradient region 8B includes a first step region 12, a first step transition region 13, a second step region 14, a second step transition region 15, and a third step region 16.

The first step region 12 has the second concentration C2 which is substantially fixed from the buffer region 7 toward the first main surface 3 side. The first step transition region 13 has a concentration gradient gradually reduced from the second concentration C2 to a fifth concentration C5 which is less than the second concentration C2 from the first step region 12 toward the first main surface 3 side. The fifth concentration C5 may also be called as the “intermediate drift concentration.”

The second step region 14 has the fifth concentration C5 which is substantially fixed from the first step transition region 13 toward the first main surface 3 side. The second step transition region 15 has a concentration gradient gradually reduced from the fifth concentration C5 to the fourth concentration C4 which is less than the fifth concentration C5 from the second step region 14 toward the first main surface 3 side. The third step region 16 has the fourth concentration C4 which is substantially fixed from the second step transition region 15 toward the first main surface 3 side.

The drift gradient region 8B forms a second electric field distribution E2 in the chip 2. The second electric field distribution E2 has a profile in which an electric field strength is monotonically increased from the buffer region 7 side toward the first main surface 3 side. That is, the second electric field distribution E2 has a maximum electric field strength in an end portion on the first main surface 3 side and has a minimum electric field strength in an end portion on the buffer region 7 side.

In the second electric field distribution E2, an increase ratio of the electric field strength on the first main surface 3 side is smaller than an increase ratio of the electric field strength on the buffer region 7 side. Also, the increase ratio of the electric field strength is gradually reduced from the buffer region 7 side toward the first main surface 3 side. Specifically, an increase ratio of the electric field strength of the second step region 14 is smaller than an increase ratio of the electric field strength of the first step region 12, and an increase ratio of the electric field strength of the third step region 16 is smaller than the increase ratio of the electric field strength of the second step region 14. Therefore, the second electric field distribution E2 is gradually increased in a broken line manner from the buffer region 7 side toward the first main surface 3 side.

Similar to FIG. 3A, FIG. 3B illustrates the concentration profile of the drift region 8C according to the reference example and the reference electric field distribution ER of the drift region 8C according to the reference example (see a double chain line). The maximum electric field strength of the reference electric field distribution ER is larger than the maximum electric field strength of the second electric field distribution E2. The minimum electric field strength of the reference electric field distribution ER is substantially equal to the minimum electric field strength of the second electric field distribution E2. The reference electric field distribution ER has a second intersection point P2 crossing the second electric field distribution E2 in an intermediate portion of a thickness range of the drift region 8C (drift gradient region 8).

A first area SB1 is formed in a range of not less than the second electric field distribution E2 and not more than the reference electric field distribution ER in a thickness range between the first main surface 3 and the second intersection point P2. A second area SB2 is formed in a range of not less than the reference electric field distribution ER and not more than the second electric field distribution E2 in a thickness range between the buffer region 7 and the second intersection point P2.

In this case, the second area SB2 is preferably adjusted to be substantially equal to the first area SB1. According to this structure, a breakdown voltage in a case where the drift gradient region 8B according to the second embodiment example is formed is substantially equal to a breakdown voltage in a case where the drift region 8C according to the reference example is formed.

With reference to FIG. 2 again, the semiconductor device 1A includes an n-type diode region 20 formed in the first main surface 3. The diode region 20 is formed in a surface layer portion of the drift gradient region 8. Specifically, the diode region 20 is formed by utilizing part of the drift gradient region 8 in the surface layer portion of the drift gradient region 8.

The semiconductor device 1A includes a p-type (second conductivity type) guard region 21 formed in a surface layer portion of the first main surface 3 along the diode region 20. In this embodiment, the guard region 21 is formed in the surface layer portion of the drift gradient region 8 such as to define the diode region 20 from the peripheral edge portion side of the first main surface 3. The guard region 21 is formed in a band shape extending along the diode region 20 in a plan view. The guard region 21 is formed in a ring shape (in this embodiment, a square ring shape) surrounding the diode region 20 in a plan view.

The semiconductor device 1A includes at least one (preferably, not less than two and not more than twenty) p-type field regions 22 formed in a region between a peripheral edge of the first main surface 3 and the guard region 21 in the surface layer portion of the first main surface 3. In this embodiment, the semiconductor device 1A includes four field regions 22.

In this embodiment, the plurality of field regions 22 are formed in the surface layer portion of the drift gradient region 8. The plurality of field regions 22 relax an electric field in the chip 2 in the peripheral edge portion of the first main surface 3. The number, a width, a depth, a p-type impurity concentration, etc., of the field regions 22 are arbitrary, and can take various values in accordance with the electric field to be relaxed.

The plurality of field regions 22 are arranged at intervals on the peripheral edge side of the first main surface 3 from the guard region 21. The plurality of field regions 22 are formed in a band shape extending along the peripheral edge of the first main surface 3 in a plan view. In this embodiment, the plurality of field regions 22 are formed in a ring shape (specifically, a square ring shape) surrounding the diode region 20 (guard region 21) in a plan view.

The semiconductor device 1A includes an insulating film 23 that selectively covers the first main surface 3. The insulating film 23 covers the plurality of field regions 22 in the peripheral edge portion of the first main surface 3, and has a contact opening 24 from which the diode region 20 and an inner edge portion of the guard region 21 are exposed in an inner side portion of the first main surface 3.

The insulating film 23 may be continuous with the peripheral edge of the first main surface 3, and may form one grinding surface with the first to fourth side surfaces 5A to 5D. As a matter of course, the insulating film 23 may be formed at an interval inward from the peripheral edge of the first main surface 3 and may expose the drift gradient region 8 from the peripheral edge portion of the first main surface 3.

The semiconductor device 1A includes a first polar electrode 25 (first main surface electrode) arranged on the first main surface 3. The first polar electrode 25 may also be called as the “anode electrode.” The first polar electrode 25 is arranged at an interval inward from the peripheral edge of the first main surface 3. In this embodiment, the first polar electrode 25 is formed in a square shape along the peripheral edge of the first main surface 3 in a plan view. The first polar electrode 25 enters the contact opening 24 from above the insulating film 23, and is electrically connected to the diode region 20 and the inner edge portion of the guard region 21. That is, the first polar electrode 25 is electrically connected to the drift gradient region 8 in the contact opening 24.

The first polar electrode 25 forms a Schottky junction with the diode region 20 (that is, the drift gradient region 8). Thereby, an SBD structure 26 serving as an example of a device structure is formed. A planar area of the first polar electrode 25 is preferably not less than 50% of the first main surface 3. The planar area of the first polar electrode 25 is particularly preferably not less than 75% of the first main surface 3. The first polar electrode 25 may have a thickness of not less than 0.5 μm and not more than 15 μm. The first polar electrode 25 is preferably thicker than the insulating film 23.

The semiconductor device 1A includes a second polar electrode 27 (second main surface electrode) that covers the second main surface 4. The second polar electrode 27 may also be called as the “cathode electrode.” The second polar electrode 27 forms ohmic contact with the base region 6 exposed from the second main surface 4. The second polar electrode 27 may cover the entire region of the second main surface 4 such as to be continuous with a peripheral edge of the chip 2 (first to fourth side surfaces 5A to 5D). The second polar electrode 27 may cover the second main surface 4 at an interval inward from the peripheral edge of the chip 2.

A breakdown voltage applicable to between the first polar electrode 25 and the second polar electrode 27 may be not less than 500 V and not more than 3,000 V. That is, the chip 2 may be formed so that the breakdown voltage of not less than 500 V and not more than 3,000 V is applied to between the first main surface 3 and the second main surface 4. The chip 2 is formed so that the electric field strength on the first main surface 3 side serving as the device surface is higher than the electric field strength on the second main surface 4 side serving as the non-device surface by a voltage application condition.

As a factor of accidental failure of the semiconductor device, single event burnout (SEB) breakdown due to cosmic rays coming down to the Earth from space is known. The cosmic rays coming down to the Earth cause a nuclear breakdown reaction with nuclei of atoms constituting the atmosphere, and produce neutrons serving as relatively-highly-permeable radial rays (high energy particles) which are difficult to be shielded.

The neutrons cause electric field abnormalities inside the semiconductor device by colliding with the semiconductor device, and generate overvoltage and overcurrent locally. As a result, the SEB breakdown is caused. Although the SEB breakdown is generated with extremely low probability, its breakdown mode is fatal in many cases. Especially, the SEB breakdown tends to be caused due to a high electric field portion inside the semiconductor device. Therefore, there is a need to lower an electric field strength in the high electric field portion and enhance a cosmic ray tolerance (SEB breakdown tolerance).

The semiconductor device 1A includes the chip 2 and the n-type drift gradient region 8. The chip 2 has the first main surface 3 serving as the device surface and the second main surface 4 serving as the non-device surface. The drift gradient region 8 is formed in the chip 2, and has a concentration profile in which the impurity concentration of the end portion on the first main surface 3 side is lower than the impurity concentration of the end portion on the second main surface 4 side (see FIGS. 3A and 3B).

In a case where a voltage drop with respect to the second main surface 4 is generated between the first main surface 3 and the second main surface 4, an electric field distribution in which the electric field strength is enhanced from the second main surface 4 side toward the first main surface 3 side is formed in the drift gradient region 8. That is, the electric field strength on the first main surface 3 side in the drift gradient region 8 is higher than the electric field strength on the second main surface 4 side in the drift gradient region 8.

In such an electric field distribution, in the drift gradient region 8, the electric field strength on the first main surface 3 side is reduced (see FIGS. 3A and 3B). Thereby, it is possible to suppress an operation of the cosmic rays (neutrons) to the high electric field portion in the drift gradient region 8. Thus, it is possible to suppress local generation of overvoltage and overcurrent due to the cosmic rays (neutrons). As a result, the cosmic ray tolerance is improved, and it is possible to suppress the SEB breakdown. Therefore, it is possible to provide the semiconductor device 1A having excellent reliability.

However, in a case where the electric field strength on the first main surface 3 side is lowered, the cosmic ray tolerance is improved but a drop of the breakdown voltage (withstand voltage) is concerned. Therefore, the drift gradient region 8 preferably has a concentration profile in which the impurity concentration is gradually lowered from the second main surface 4 side toward the first main surface 3 side (see FIGS. 3A and 3B).

According to this structure, it is possible to enhance the electric field strength on the second main surface 4 side while maintaining a state where the electric field strength on the first main surface 3 side is lowered (see FIGS. 3A and 3B). Thereby, it is possible to supplement a drop amount of the breakdown voltage (withstand voltage) due to a decrease in the electric field strength on the first main surface 3 side with an increase amount of the breakdown voltage (withstand voltage) due to an increase in the electric field strength on the second main surface 4 side. Therefore, it is possible to improve the cosmic ray tolerance while maintaining the withstand voltage.

The drift gradient region 8 preferably forms an electric field distribution in which the electric field strength is monotonically increased from the second main surface 4 side toward the first main surface 3 side (see FIGS. 3A and 3B). The drift gradient region 8 preferably forms an electric field distribution in which the increase ratio of the electric field strength on the first main surface 3 side is smaller than the increase ratio of the electric field strength on the second main surface 4 side (see FIGS. 3A and 3B).

The drift gradient region 8 may have a concentration profile in which the n-type impurity concentration is lowered in a downward inclining manner toward the first main surface 3 side (see FIG. 3A). The drift gradient region 8 may have a concentration profile in which the n-type impurity concentration is lowered in a downward staircase manner toward the first main surface 3 side (see FIG. 3B).

The chip 2 preferably includes a single crystal of a wide-bandgap semiconductor. According to this structure, it is possible to provide the wide-bandgap semiconductor device (semiconductor device 1A) serving as a power semiconductor device with which a high voltage and a high electric field are applicable. Since the wide-bandgap semiconductor device is used under an environment of a high voltage and a high electric field, a risk of the SEB breakdown is higher than a Si semiconductor device. At this point, with the drift gradient region 8, it is possible to improve the cosmic ray tolerance by a decrease in the electric field strength on the first main surface 3 side, and hence the SEB breakdown is suppressed. Therefore, even in a case where the semiconductor device 1A is formed by the wide-bandgap semiconductor device, it is also possible to improve reliability.

Also, with the semiconductor device 1A serving as the wide-bandgap semiconductor device, by reduction of the risk of the SEB breakdown, it is possible to indirectly improve reliability of applications to be installed. For example, by installing the semiconductor device 1A serving as the wide-bandgap semiconductor device in a vehicle, etc., having a motor as a drive source such as a hybrid vehicle, an electric vehicle, and a fuel-cell-powered vehicle, it is possible to enhance safety while reducing power consumption of these applications.

The chip 2 preferably includes an SiC single crystal serving as an example of the single crystal of the wide-bandgap semiconductor. In this case, it is possible to provide the SiC semiconductor device (semiconductor device 1A) having excellent reliability. A breakdown voltage applicable to between the first main surface 3 and the second main surface 4 may be not less than 500 V and not more than 3,000 V. The chip 2 may have a thickness of not more than 200 μm. The chip 2 preferably has a thickness of not more than 150 μm.

The chip 2 may have the first main surface 3 having a planar area of not less than 1 mm square. With the chip 2 having the relatively large planar area, a current processing ability is improved. Thus, electrical characteristics are improved. However, in a case where the planar area of the chip 2 is increased, a collision risk of the cosmic rays is enhanced. At this point, with the drift gradient region 8, it is possible to improve the cosmic ray tolerance by the decrease in the electric field strength on the first main surface 3 side having the relatively large planar area. Therefore, even in a case where the first main surface 3 having the relatively large planar area is adopted, it is possible to suppress the SEB breakdown.

The drift gradient region 8 may form the first main surface 3. In this case, the semiconductor device 1A may include the first polar electrode 25 arranged on the drift gradient region 8 such as to form a Schottky junction with the drift gradient region 8. According to this structure, it is possible to provide the semiconductor device 1A having the SBD structure 26. The semiconductor device 1A may include the second polar electrode 27 arranged on the second main surface 4. According to this structure, it is possible to provide the semiconductor device 1A having the vertical type SBD structure 26 in which a forward-direction electric current flows from the first main surface 3 toward the second main surface 4.

The semiconductor device 1A may include the n-type diode region 20 formed by utilizing part of the drift gradient region 8. The semiconductor device 1A may include the p-type guard region 21 formed along the diode region 20 in the surface layer portion of the first main surface 3. In this case, the first polar electrode 25 may cover the diode region 20 and the guard region 21 such as to form a Schottky junction with the diode region 20 and to be electrically connected to the guard region 21.

The semiconductor device 1A may include the n-type base region 6 formed in a region on the second main surface 4 side in the chip 2. The semiconductor device 1A may include the buffer region 7 formed in a region on the first main surface 3 side with respect to the base region 6 in the chip 2. In this case, the drift gradient region 8 is preferably formed in a region on the first main surface 3 side with respect to the buffer region 7 in the chip 2. The buffer region 7 preferably has the impurity concentration lower than the base region 6. The drift gradient region 8 preferably has the impurity concentration lower than the buffer region 7.

The buffer region 7 preferably has the thickness less than the thickness of the base region 6. The drift gradient region 8 is preferably thicker than the buffer region 7. The base region 6 may have the thickness of not less than 1 μm and not more than 200 μm. The buffer region 7 may have the thickness of not less than 0.1 μm and not more than 5 μm. The drift gradient region 8 may have the thickness of not less than 1 μm and not more than 50 μm.

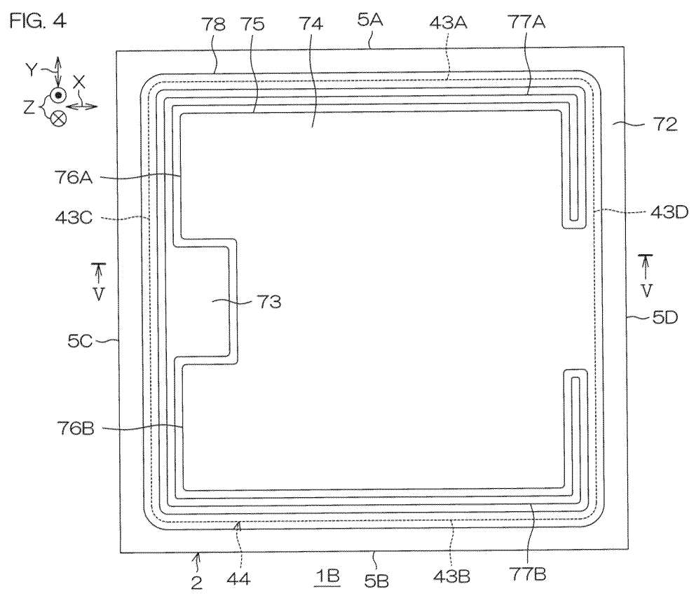

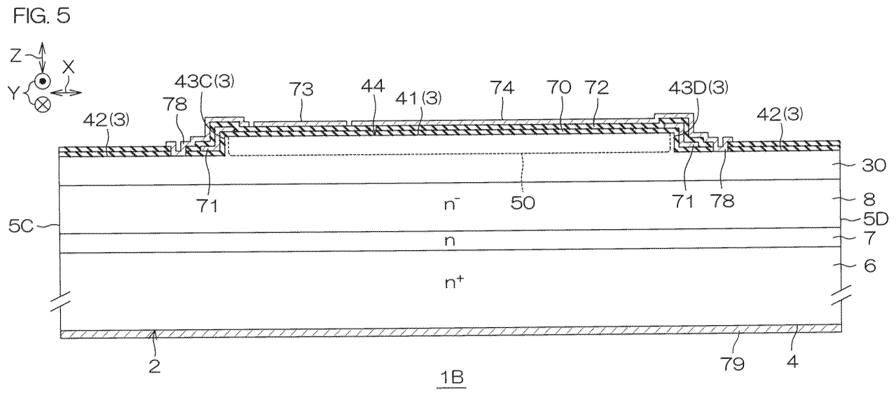

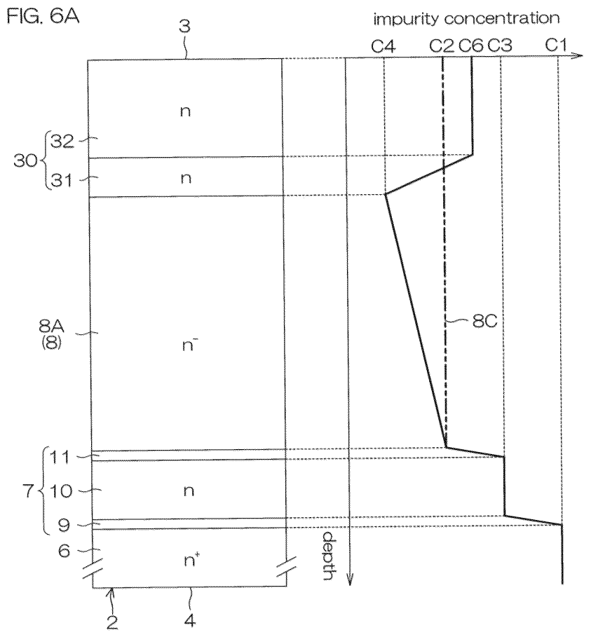

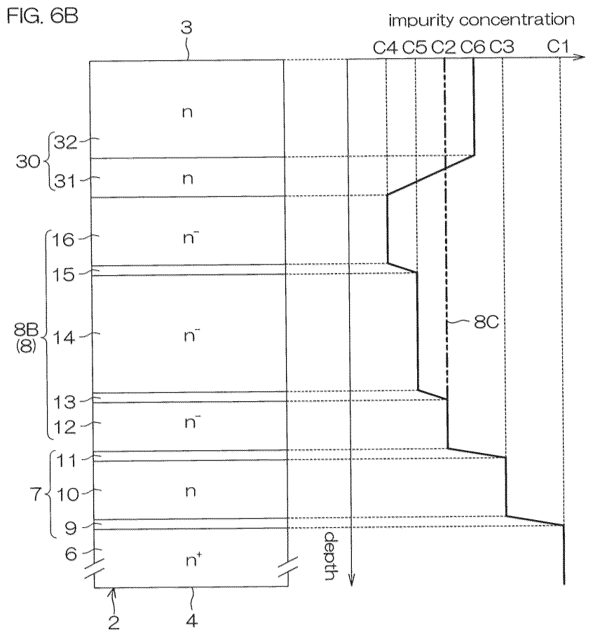

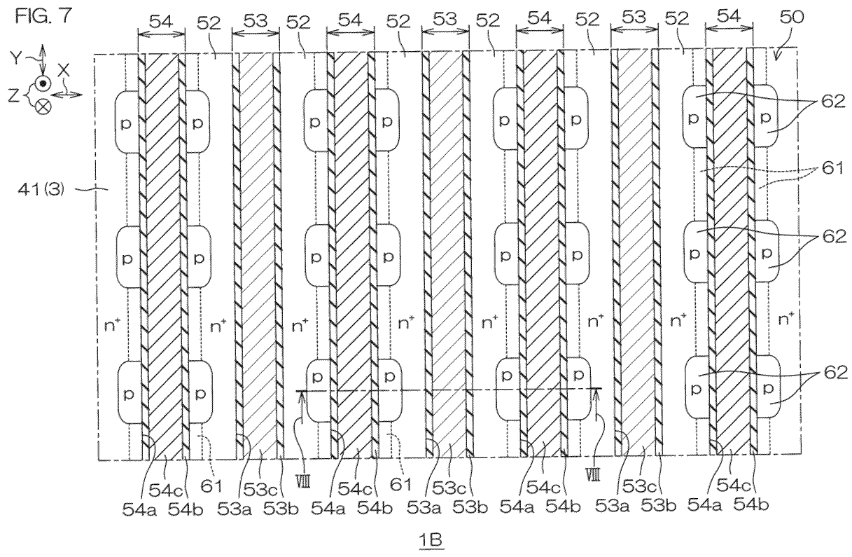

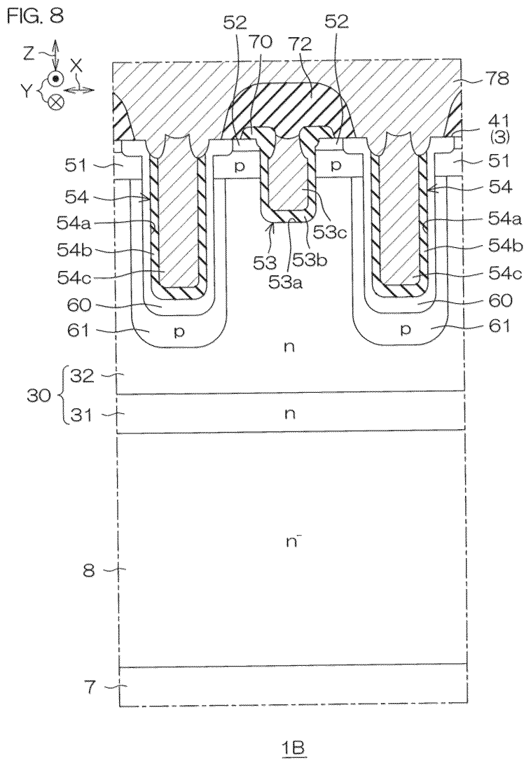

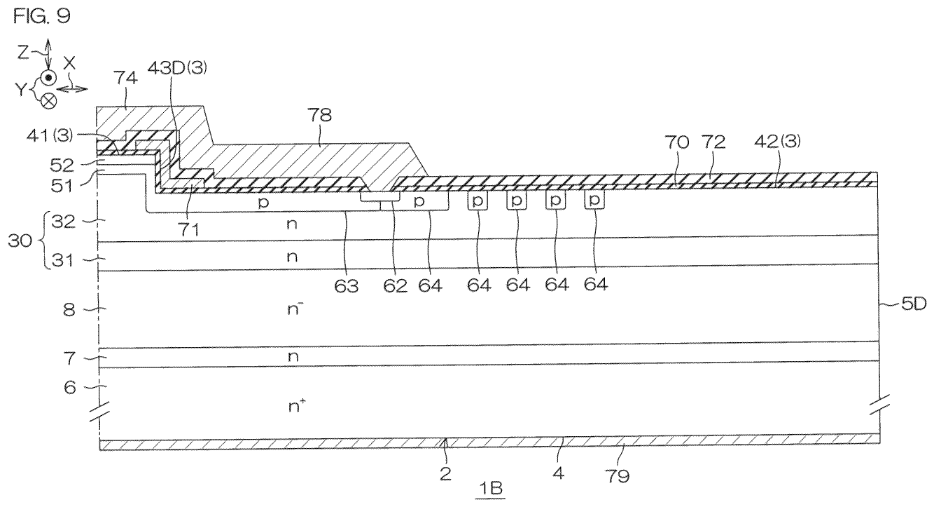

FIG. 4 is a plan view illustrating a semiconductor device 1B according to a second embodiment. FIG. 5 is a cross-sectional view taken along line V-V illustrated in FIG. 3. FIG. 6A is a diagram for describing a concentration distribution in a chip 2 together with a drift gradient region 8A according to a first embodiment example. FIG. 6B is a diagram for describing a concentration distribution in the chip 2 together with a drift gradient region 8B according to a second embodiment example. FIG. 7 is a plan view illustrating major parts of the semiconductor device 1B illustrated in FIG. 3. FIG. 8 is a cross-sectional view taken along line VIII-VIII illustrated in FIG. 7. FIG. 9 is an enlarged cross-sectional view illustrating a peripheral edge portion of the chip 2.

With reference to FIGS. 4 to 6B, the semiconductor device 1B includes the chip 2, a base region 6, a buffer region 7, and a drift gradient region 8 similarly to the semiconductor device 1A described above. With reference to FIG. 6A, the semiconductor device 1B may include the drift gradient region 8A according to the first embodiment example. With reference to FIG. 6B, the semiconductor device 1B may include the drift gradient region 8B according to the second embodiment example. The chip 2, the base region 6, the buffer region 7, and the drift gradient region 8 (8A, 8B) have similar modes to the semiconductor device 1A.

In this embodiment, the semiconductor device 1B includes an n-type drift high concentration region 30 formed in a region on the first main surface 3 side with respect to the drift gradient region 8 in the chip 2. The drift high concentration region 30 is formed in a layer shape extending along the drift gradient region 8 so that the drift high concentration region 30 is connected to the drift gradient region 8, and exposed from the first main surface 3 and first to fourth side surfaces 5A to 5D. In this embodiment, the drift high concentration region 30 is exposed from the entire region of the first main surface 3. That is, the drift high concentration region 30 forms the first main surface 3.

The drift high concentration region 30 has an n-type impurity concentration higher than the drift gradient region 8. The n-type impurity concentration of the drift high concentration region 30 is preferably set within a range of not less than 1×10¹⁵ cm⁻³ and not more than 1×10¹⁸ cm⁻³. In this embodiment, the drift high concentration region 30 is formed by an epitaxial layer (specifically, an SiC epitaxial layer) laminated on the drift gradient region 8 (epitaxial layer).

The drift high concentration region 30 is preferably thicker than the buffer region 7. A thickness of the drift high concentration region 30 is preferably less than a thickness of the drift gradient region 8. The thickness of the drift high concentration region 30 may be not less than 1 μm and not more than 10 μm. The thickness of the drift high concentration region 30 is preferably not less than 3 μm and not more than 5 μm.

With reference to FIGS. 6A and 6B, the drift high concentration region 30 includes a high concentration transition region 31 and a high concentration holding region 32. The high concentration transition region 31 has a concentration profile in which an impurity concentration is gradually increased from a fourth concentration C4 to a sixth concentration C6 which is higher than the fourth concentration C4 from the drift gradient region 8 toward the first main surface 3 side. The sixth concentration C6 may also be called as the “high drift concentration.”

The high concentration holding region 32 has the sixth concentration C6 which is substantially fixed from the high concentration transition region 31 toward the first main surface 3 side. The sixth concentration C6 is less than a first concentration C1 of the base region 6. The sixth concentration C6 is preferably higher than a second concentration C2 of the buffer region 7, and lower than a third concentration C3 of the buffer region 7.

With reference to FIGS. 4 and 5 again, the semiconductor device 1B includes an active surface 41, an outer surface 42, and first to fourth connecting surfaces 43A to 43D formed in the first main surface 3. The active surface 41, the outer surface 42, and the first to fourth connecting surfaces 43A to 43D define a mesa portion 44 (plateau) in the first main surface 3.

The active surface 41 may be called as the “first surface portion,” the outer surface 42 may be called as the “second surface portion,” and the first to fourth connecting surfaces 43A to 43D may be called as the “connecting surface portions.” The active surface 41, the outer surface 42, and the first to fourth connecting surfaces 43A to 43D (that is, the mesa portion 44) may be regarded as constituent elements of the chip 2 (first main surface 3).

The active surface 41 is formed in an inner side portion of the first main surface 3 at an interval from a peripheral edge of the first main surface 3 (first to fourth side surfaces 5A to 5D). The active surface 41 is formed by the drift high concentration region 30. Specifically, the active surface 41 is formed by the high concentration holding region 32. The active surface 41 has a flat surface extending in the first direction X and the second direction Y. In this embodiment, the active surface 41 is formed in a square shape having four sides parallel to the first to fourth side surfaces 5A to 5D in a plan view.

The outer surface 42 is placed in a peripheral edge portion of the first main surface 3 and hollowed in the thickness direction of the chip 2 (to the second main surface 4 side) from the active surface 41. The outer surface 42 is hollowed at a depth less than the thickness of the drift high concentration region 30 so that the drift high concentration region 30 is exposed. Specifically, the outer surface 42 is formed at an interval from the high concentration transition region 31 and formed by the high concentration holding region 32.

The outer surface 42 extends in a band shape along the active surface 41 in a plan view, and is formed in a ring shape (specifically, a square ring shape) surrounding the active surface 41. The outer surface 42 has a flat surface extending in the first direction X and the second direction Y, and is formed substantially in parallel to the active surface 41. The outer surface 42 is continuous with the first to fourth side surfaces 5A to 5D.

The first connecting surface 43A is placed on the first side surface 5A side, the second connecting surface 43B is placed on the second side surface 5B side, the third connecting surface 43C is placed on the third side surface 5C side, and the fourth connecting surface 43D is placed on the fourth side surface 5D side. The first connecting surface 43A and the second connecting surface 43B extend in the first direction X and oppose each other in the second direction Y. The third connecting surface 43C and the fourth connecting surface 43D extend in the second direction Y and oppose each other in the first direction X.

The first to fourth connecting surfaces 43A to 43D extend in the normal direction Z and connect the active surface 41 and the outer surface 42. The first to fourth connecting surfaces 43A to 43D are formed by the drift high concentration region 30. Specifically, the first to fourth connecting surfaces 43A to 43D are formed at an interval from the high concentration transition region 31 and formed by the high concentration holding region 32.

The first to fourth connecting surfaces 43A to 43D may extend substantially perpendicularly between the active surface 41 and the outer surface 42 so that the quadrangle columnar shaped mesa portion 44 is defined. The first to fourth connecting surfaces 43A to 43D may be obliquely-downward inclined from the active surface 41 toward the outer surface 42 so that the quadrangular frustum shaped mesa portion 44 is defined.

In such a way, the semiconductor device 1B includes the mesa portion 44 formed in the drift high concentration region 30 in the first main surface 3. The mesa portion 44 is formed only in the drift high concentration region 30 and does not expose the drift gradient region 8. Specifically, the mesa portion 44 is formed in the high concentration holding region 32 and does not expose the high concentration transition region 31.

The semiconductor device 1B includes a metal insulator semiconductor field effect transistor (MISFET) structure 50 formed in the active surface 41 (first main surface 3) as an example of a device structure. In FIG. 5, the MISFET structure 50 is simplified and illustrated by a broken line. Hereinafter, the MISFET structure 50 and a structure on the outer surface 42 side will be specifically described.

With reference to FIGS. 7 to 9, the MISFET structure 50 includes a p-type (second conductivity type) body region 51 formed in a surface layer portion of the active surface 41. The body region 51 is formed in a surface layer portion of the drift high concentration region 30 at an interval on the active surface 41 side from the drift gradient region 8. Specifically, the body region 51 is formed in a surface layer portion of the high concentration holding region 32 at an interval on the active surface 41 side from the high concentration transition region 31 and formed in a layer shape extending along the active surface 41. The body region 51 may be exposed from part of the first to fourth connecting surfaces 43A to 43D.

The MISFET structure 50 includes an n-type source region 52 formed in a surface layer portion of the body region 51. The source region 52 has an n-type impurity concentration higher than the drift high concentration region 30. The source region 52 is formed at an interval on the active surface 41 side from a bottom portion of the body region 51.

The source region 52 is formed in a layer shape extending along the active surface 41. The source region 52 may be exposed from the entire region of the active surface 41. The source region 52 may be exposed from part of the first to fourth connecting surfaces 43A to 43D. The source region 52 forms a channel in the body region 51 between the source region 52 and the drift high concentration region 30.

The MISFET structure 50 includes a plurality of trench gate structures 53 formed in the active surface 41. The plurality of trench gate structures 53 are arranged at intervals in the first direction X in a plan view, and respectively formed in a band shape extending in the second direction Y. The plurality of trench gate structures 53 are formed in the surface layer portion of the drift high concentration region 30 at an interval on the active surface 41 side from the drift gradient region 8.

Specifically, the plurality of trench gate structures 53 are formed at an interval on the active surface 41 side from the high concentration transition region 31, pass through the body region 51 and the source region 52, and reach the high concentration holding region 32. The plurality of trench gate structures 53 control reversal and non-reversal of the channel in the body region 51.

In this embodiment, each trench gate structure 53 includes a gate trench 53a, a gate insulating film 53b, and a gate embedded electrode 53c. The gate trench 53a is formed in the active surface 41 and defines a wall surface of the trench gate structure 53. The gate insulating film 53b covers a wall surface of the gate trench 53a. The gate embedded electrode 53c is embedded in the gate trench 53a across the gate insulating film 53b, and opposes the channel across the gate insulating film 53b.

The MISFET structure 50 includes a plurality of trench source structures 54 formed in the active surface 41. Each of the plurality of trench source structures 54 is formed in a region between the pair of adjacent trench gate structures 53 in the active surface 41. The plurality of trench source structures 54 are respectively formed in a band shape extending in the second direction Y in a plan view.

The plurality of trench source structures 54 are formed in the surface layer portion of the drift high concentration region 30 at an interval on the active surface 41 side from the drift gradient region 8. Specifically, the plurality of trench source structures 54 are formed at an interval on the active surface 41 side from the high concentration transition region 31, pass through the body region 51 and the source region 52, and reach the high concentration holding region 32.

The plurality of trench source structures 54 are formed to be deeper than the trench gate structures 53. The plurality of trench source structures 54 may have a depth not less than 1.5 times and not more than 4 times of a depth of the plurality of trench gate structures 53. The depth of the plurality of trench source structures 54 is preferably not more than 2.5 times of the depth of the plurality of trench gate structures 53. In this embodiment, the plurality of trench source structures 54 have the depth substantially equal to the depth of the outer surface 42. As a matter of course, the plurality of trench source structures 54 may have the depth substantially equal to the plurality of trench gate structures 53.

Each trench source structure 54 includes a source trench 54a, a source insulating film 54b, and a source embedded electrode 54c. The source trench 54a is formed in the active surface 41 and defines a wall surface of the trench source structure 54. The source insulating film 54b covers a wall surface of the source trench 54a. The source embedded electrode 54c is embedded in the source trench 54a across the source insulating film 54b.

The MISFET structure 50 includes a plurality of p-type contact regions 60 respectively formed in regions along the plurality of trench source structures 54 in the chip 2. The plurality of contact regions 60 have a p-type impurity concentration higher than the body region 51. Each contact region 60 covers a side wall and a bottom wall of each trench source structure 54, and is electrically connected to the body region 51. Each contact region 60 is formed in the drift high concentration region 30 at an interval on the active surface 41 side from the drift gradient region 8. Specifically, each contact region 60 is formed in the high concentration holding region 32 at an interval on the active surface 41 side from the high concentration transition region 31.

The MISFET structure 50 includes a plurality of p-type well regions 61 respectively formed in regions along the plurality of trench source structures 54 in the chip 2. Each well region 61 may have a p-type impurity concentration higher than the body region 51 and lower than the contact regions 60. Each contact region 61 covers the corresponding trench source structure 54 across the corresponding contact region 60.

Each well region 61 covers the side wall and the bottom wall of the corresponding trench source structure 54, and is electrically connected to the body region 51 and the contact region 60. Each well region 61 is formed in the drift high concentration region 30 at an interval on the active surface 41 side from the drift gradient region 8. Specifically, each well region 61 is formed in the high concentration holding region 32 at an interval on the active surface 41 side from the high concentration transition region 31.

With reference to FIG. 9, the semiconductor device 1B includes a p-type outer contact region 62 formed in a surface layer portion of the outer surface 42. The outer contact region 62 has a p-type impurity concentration exceeding the p-type impurity concentration of the body region 51. The outer contact region 62 preferably has the p-type impurity concentration substantially equal to the p-type impurity concentration of the contact regions 60.

The outer contact region 62 is formed at an interval from a peripheral edge of the active surface 41 and a peripheral edge of the outer surface 42 in a plan view, and formed in a band shape extending along the active surface 41. In this embodiment, the outer contact region 62 is formed in a ring shape (specifically, a square ring shape) surrounding the active surface 41 in a plan view.

The outer contact region 62 is formed in the surface layer portion of the drift high concentration region 30 at an interval on the outer surface 42 side from the drift gradient region 8. Specifically, the outer contact region 62 is formed in the high concentration holding region 32 at an interval on the outer surface 42 side from the high concentration transition region 31. The outer contact region 62 is placed on the bottom portion side of the drift high concentration region 30 with respect to bottom walls of the plurality of trench gate structures 53 (trench source structures 54).

The semiconductor device 1B includes a p-type outer well region 63 formed in the surface layer portion of the outer surface 42. The outer well region 63 has a p-type impurity concentration less than the p-type impurity concentration of the outer contact region 62. The p-type impurity concentration of the outer well region 63 is preferably substantially equal to the p-type impurity concentration of the well regions 61.

The outer well region 63 is formed in a region between the active surface 41 and the outer contact region 62 in a plan view, and formed in a band shape extending along the active surface 41. In this embodiment, the outer well region 63 is formed in a ring shape (specifically, a square ring shape) surrounding the active surface 41 in a plan view.

The outer well region 63 is formed in the surface layer portion of the drift high concentration region 30 at an interval on the outer surface 42 side from the drift gradient region 8. Specifically, the outer well region 63 is formed in the high concentration holding region 32 at an interval on the outer surface 42 side from the high concentration transition region 31. The outer well region 63 is placed on the bottom portion side of the drift high concentration region 30 with respect to the bottom walls of the plurality of trench gate structures 53 (trench source structures 54).

The outer well region 63 is electrically connected to the outer contact region 62. In this embodiment, the outer well region 63 extends from the outer contact region 62 side toward the first to fourth connecting surfaces 43A to 43D and covers the first to fourth connecting surfaces 43A to 43D. The outer well region 63 is electrically connected to the body region 51 in the surface layer portion of the active surface 41.

The semiconductor device 1B includes at least one (preferably, not less than two and not more than twenty) p-type field regions 64 formed in a region between the peripheral edge of the outer surface 42 and the outer contact region 62 in the surface layer portion of the outer surface 42. In this embodiment, the semiconductor device 1B includes five field regions 64. The plurality of field regions 64 relax an electric field in the chip 2 in the outer surface 42. The number, a width, a depth, a p-type impurity concentration, etc., of the field regions 64 are arbitrary, and can take various values in accordance with the electric field to be relaxed.

The plurality of field regions 64 are arranged at intervals on the peripheral edge side of the outer surface 42 from the outer contact region 62 side. The plurality of field regions 64 are formed in a band shape extending along the active surface 41 in a plan view. In this embodiment, the plurality of field regions 64 are formed in a ring shape (specifically, a square ring shape) surrounding the active surface 41 in a plan view.

The plurality of field regions 64 are formed in the surface layer portion of the drift high concentration region 30 at an interval on the outer surface 42 side from the drift gradient region 8. Specifically, the plurality of field regions 64 are formed in the high concentration holding region 32 at an interval on the outer surface 42 side from the high concentration transition region 31.

The plurality of field regions 64 are placed on the bottom portion side of the drift high concentration region 30 with respect to the bottom walls of the plurality of trench gate structures 53 (trench source structures 54). The plurality of field regions 64 may be formed to be deeper than the outer contact region 62. The innermost field region 64 may be connected to the outer contact region 62.

The semiconductor device 1B includes a main surface insulating film 70 that covers the first main surface 3. The main surface insulating film 70 may include at least one of a silicon oxide film, a silicon nitride film, and a silicon oxynitride film. In this embodiment, the main surface insulating film 70 has a single-layer structure formed by a silicon oxide film. The main surface insulating film 70 particularly preferably includes a silicon oxide film made of oxide of the chip 2.

The main surface insulating film 70 covers the active surface 41, the outer surface 42, and the first to fourth connecting surfaces 43A to 43D. The main surface insulating film 70 is continuous with the gate insulating film 53b and the source insulating film 54b, and covers the active surface 41 so that the gate embedded electrode 53c and the source embedded electrode 54c are exposed. The main surface insulating film 70 covers the outer surface 42 and the first to fourth connecting surfaces 43A to 43D such as to cover the outer contact region 62, the outer well region 63, and the plurality of field regions 64.

The main surface insulating film 70 may be continuous with the first to fourth side surfaces 5A to 5D. In this case, an outer wall of the main surface insulating film 70 may form one grinding surface with the first to fourth side surfaces 5A to 5D. As a matter of course, the outer wall of the main surface insulating film 70 may be formed at an interval inward from the peripheral edge of the outer surface 42 and expose the drift high concentration region 30 from a peripheral edge portion of the outer surface 42.

The semiconductor device 1B includes a side wall structure 71 formed on the main surface insulating film 70 such as to cover at least one of the first to fourth connecting surfaces 43A to 43D in the outer surface 42. In this embodiment, the side wall structure 71 is formed in a ring shape (square ring shape) surrounding the active surface 41 in a plan view.

The side wall structure 71 may have a part that rides on the active surface 41. The side wall structure 71 may include an inorganic insulating body or polysilicon. The side wall structure 71 may be a side wall wiring electrically connected to the trench source structure 54.

The semiconductor device 1B includes an interlayer insulating film 72 formed on the main surface insulating film 70. The interlayer insulating film 72 may include at least one of a silicon oxide film, a silicon nitride film, and a silicon oxynitride film. In this embodiment, the interlayer insulating film 72 includes a silicon oxide film. The interlayer insulating film 72 covers the active surface 41, the outer surface 42, and the first to fourth connecting surfaces 43A to 43D across the main surface insulating film 70.

Specifically, the interlayer insulating film 72 covers the active surface 41, the outer surface 42, and the first to fourth connecting surfaces 43A to 43D via the side wall structure 71. The interlayer insulating film 72 covers the MISFET structure 50 on the active surface 41 side, and covers the outer contact region 62, the outer well region 63, and the plurality of field regions 64 on the outer surface 42 side.

In this embodiment, the interlayer insulating film 72 is continuous with the first to fourth side surfaces 5A to 5D. An outer wall of the interlayer insulating film 72 may form one grinding surface with the first to fourth side surfaces 5A to 5D. As a matter of course, the outer wall of the interlayer insulating film 72 may be formed at an interval inward from the peripheral edge of the outer surface 42 and expose the drift high concentration region 30 from the peripheral edge portion of the outer surface 42.

The semiconductor device 1B includes a gate electrode 73 arranged on the first main surface 3 (interlayer insulating film 72). The gate electrode 73 is arranged in the inner side portion of the first main surface 3 at an interval from the peripheral edge of the first main surface 3. In this embodiment, the gate electrode 73 is arranged on the active surface 41. Specifically, the gate electrode 73 is arranged in a region close to a central portion of the third connecting surface 43C (third side surface 5C) in the peripheral edge portion of the active surface 41.

In this embodiment, the gate electrode 73 is formed in a square shape in a plan view. As a matter of course, the gate electrode 73 may be formed in a polygonal shape other than the square shape, a circular shape, or an oval shape in a plan view. The gate electrode 73 preferably has a planar area of not more than 25% of the first main surface 3. The planar area of the gate electrode 73 may be not more than 10% of the first main surface 3. The gate electrode 73 may have a thickness of not less than 0.5 μm and not more than 15 μm.

The semiconductor device 1B includes a source electrode 74 arranged on the first main surface 3 (interlayer insulating film 72) at an interval from the gate electrode 73. The source electrode 74 is arranged in the inner side portion of the first main surface 3 at an interval from the peripheral edge of the first main surface 3. In this embodiment, the source electrode 74 is arranged on the active surface 41. In this embodiment, the source electrode 74 has a main body electrode portion 75, and at least one (in this embodiment, a plurality of) drawer electrode portions 76A, 76B.

The main body electrode portion 75 is arranged in a region on the fourth side surface 5D (fourth connecting surface 43D) side at an interval from the gate electrode 73 in a plan view, and opposes the gate electrode 73 in the first direction X. In this embodiment, the main body electrode portion 75 is formed in a polygonal shape (specifically, a square shape) having four sides parallel to the first to fourth side surfaces 5A to 5D in a plan view.

The plurality of drawer electrode portions 76A, 76B include a first drawer electrode portion 76A on one side (on the first side surface 5A side), and a second drawer electrode portion 76B on the other side (on the second side surface 5B side). The first drawer electrode portion 76A is drawn from the main body electrode portion 75 to a region placed on one side (on the first side surface 5A side) of the second direction Y with respect to the gate electrode 73 in a plan view, and opposes the gate electrode 73 in the second direction Y.

The second drawer electrode portion 76B is drawn from the main body electrode portion 75 to a region placed on the other side (on the second side surface 5B side) of the second direction Y with respect to the gate electrode 73 in a plan view, and opposes the gate electrode 73 in the second direction Y. That is, the plurality of drawer electrode portions 76A, 76B sandwich the gate electrode 73 from both the sides of the second direction Y in a plan view.

The source electrode 74 (the main body electrode portion 75 and the drawer electrode portions 76A, 76B) passes through the interlayer insulating film 72 and the main surface insulating film 70, and is electrically connected to the plurality of trench source structures 54, the source region 52, and the plurality of well regions 61. As a matter of course, the source electrode 74 may be formed only by the main body electrode portion 75 without having the drawer electrode portions 76A, 76B.

The source electrode 74 has a planar area exceeding the planar area of the gate electrode 73. The planar area of the source electrode 74 is preferably not less than 50% of the first main surface 3. The planar area of the source electrode 74 is particularly preferably not less than 75% of the first main surface 3. The source electrode 74 may have a thickness of not less than 0.5 μm and not more than 15 μm. The source electrode 74 preferably includes the same conductive material as the gate electrode 73.

The semiconductor device 1B includes at least one (in this embodiment, a plurality of) gate wirings 77A, 77B drawn from the gate electrode 73 onto the first main surface 3 (interlayer insulating film 72). The plurality of gate wirings 77A, 77B preferably include the same conductive material as the gate electrode 73. In this embodiment, the plurality of gate wirings 77A, 77B cover the active surface 41 and do not cover the outer surface 42. The plurality of gate wirings 77A, 77B are drawn to a region between the peripheral edge of the active surface 41 and the source electrode 74 in a plan view, and extend in a band shape along the source electrode 74.

Specifically, the plurality of gate wirings 77A, 77B include a first gate wiring 77A and a second gate wiring 77B. The first gate wiring 77A is drawn from the gate electrode 73 to a region on the first side surface 5A side in a plan view. The first gate wiring 77A has a part extending in a band shape in the second direction Y along the third side surface 5C and a part extending in a band shape in the first direction X along the first side surface 5A. The second gate wiring 77B is drawn from the gate electrode 73 to a region on the second side surface 5B side in a plan view. The second gate wiring 77B has a part extending in a band shape in the second direction Y along the third side surface 5C and a part extending in a band shape in the first direction X along the second side surface 5B.

The plurality of gate wirings 77A, 77B cross (specifically, are orthogonal to) both end portions of the plurality of trench gate structures 53 in the peripheral edge portion of the active surface 41 (first main surface 3). The plurality of gate wirings 77A, 77B pass through the interlayer insulating film 72 and are electrically connected to the plurality of trench gate structures 53. The plurality of gate wirings 77A, 77B may be directly connected to the plurality of trench gate structures 53 or may be electrically connected to the plurality of trench gate structures 53 via a conductor film.

The semiconductor device 1B includes a source wiring 78 drawn from the source electrode 74 onto the first main surface 3 (interlayer insulating film 72). The source wiring 78 preferably includes the same conductive material as the source electrode 74. The source wiring 78 is formed in a band shape extending along the peripheral edge of the active surface 41 in a region on the outer surface 42 side of the plurality of gate wirings 77A, 77B. In this embodiment, the source wiring 78 is formed in a ring shape (specifically, a square ring shape) surrounding the gate electrode 73, the source electrode 74, and the plurality of gate wirings 77A, 77B in a plan view.

The source wiring 78 covers the side wall structure 71 across the interlayer insulating film 72 and is drawn from the active surface 41 side to the outer surface 42 side. The source wiring 78 preferably covers the entire region of the side wall structure 71 over the entire circumference. The source wiring 78 has a part passing through the interlayer insulating film 72 and the main surface insulating film 70 on the outer surface 42 side, the part being connected to the outer surface 42 (specifically, the outer contact region 62). The source wiring 78 may pass through the interlayer insulating film 72 and may be electrically connected to the side wall structure 71.

The semiconductor device 1B includes a drain electrode 79 that covers the second main surface 4. The drain electrode 79 forms ohmic contact with the base region 6 exposed from the second main surface 4. The drain electrode 79 may cover the entire region of the second main surface 4 such as to be continuous with the peripheral edge of the chip 2 (first to fourth side surfaces 5A to 5D). The drain electrode 79 may cover the second main surface 4 at an interval inward from the peripheral edge of the chip 2.

A breakdown voltage applicable to between the source electrode 74 and the drain electrode 79 may be not less than 500 V and not more than 3,000 V. That is, the chip 2 may be formed so that the breakdown voltage of not less than 500 V and not more than 3,000 V is applied to between the first main surface 3 and the second main surface 4. Also, the chip 2 is formed so that an electric field strength on the first main surface 3 side serving as the device surface is higher than an electric field strength on the second main surface 4 side serving as the non-device surface by a voltage application condition.

As described above, the semiconductor device 1B includes the chip 2 and the n-type drift gradient region 8. The chip 2 has the first main surface 3 serving as the device surface and the second main surface 4 serving as the non-device surface. The drift gradient region 8 is formed in the chip 2, and has the concentration profile in which the impurity concentration of the end portion on the first main surface 3 side is lower than the impurity concentration of the end portion on the second main surface 4 side (see FIGS. 6A and 6B).

In a case where a voltage drop with respect to the second main surface 4 is generated between the first main surface 3 and the second main surface 4, an electric field distribution in which the electric field strength is enhanced from the second main surface 4 side toward the first main surface 3 side is formed in the drift gradient region 8. That is, the electric field strength on the first main surface 3 side in the drift gradient region 8 is higher than the electric field strength on the second main surface 4 side in the drift gradient region 8.

In such an electric field distribution, in the drift gradient region 8, the electric field strength on the first main surface 3 side is reduced. Thereby, it is possible to suppress an operation of cosmic rays (neutrons) to a high electric field portion in the drift gradient region 8. Thus, it is possible to suppress local generation of overvoltage and overcurrent due to the cosmic rays (neutrons). As a result, a cosmic ray tolerance is improved, and it is possible to suppress SEB breakdown. Therefore, it is possible to provide the semiconductor device 1B having excellent reliability.

However, in a case where the electric field strength on the first main surface 3 side is lowered, the cosmic ray tolerance is improved but a drop of the breakdown voltage (withstand voltage) is concerned. Therefore, the drift gradient region 8 preferably has a concentration profile in which the impurity concentration is gradually lowered from the second main surface 4 side toward the first main surface 3 side (see FIGS. 6A and 6B).

According to this structure, it is possible to enhance the electric field strength on the second main surface 4 side while maintaining a state where the electric field strength on the first main surface 3 side is lowered. Thereby, it is possible to supplement a drop amount of the breakdown voltage (withstand voltage) due to a decrease in the electric field strength on the first main surface 3 side with an increase amount of the breakdown voltage (withstand voltage) due to an increase in the electric field strength on the second main surface 4 side. Therefore, it is possible to improve the cosmic ray tolerance while maintaining the withstand voltage.

The drift gradient region 8 preferably forms an electric field distribution in which the electric field strength is monotonically increased from the second main surface 4 side toward the first main surface 3 side. The drift gradient region 8 preferably forms an electric field distribution in which the increase ratio of the electric field strength on the first main surface 3 side is smaller than the increase ratio of the electric field strength on the second main surface 4 side.

The drift gradient region 8 may have a concentration profile in which the n-type impurity concentration is lowered in a downward inclining manner toward the first main surface 3 side (see FIG. 6A). The drift gradient region 8 may have a concentration profile in which the n-type impurity concentration is lowered in a downward staircase manner toward the first main surface 3 side (see FIG. 6B).

The semiconductor device 1B preferably includes the drift high concentration region 30 formed in the region on the first main surface 3 side with respect to the drift gradient region 8 in the chip 2, the drift high concentration region having the impurity concentration higher than the drift gradient region 8. According to this structure, it is possible to form a region of lower resistance than the drift gradient region 8 in the region on the first main surface 3 side by the drift high concentration region 30. The drift high concentration region 30 may have a thickness less than the thickness of the drift gradient region 8.

The drift high concentration region 30 preferably has the high concentration transition region 31 in which the impurity concentration is increased from the drift gradient region 8 toward the first main surface 3 side, and the high concentration holding region 32 having the impurity concentration which is substantially fixed from the high concentration transition region 31 toward the first main surface 3 side. The high concentration holding region 32 is preferably thicker than the high concentration transition region 31.

The semiconductor device 1B preferably includes the trench gate structure 53 formed in the first main surface 3 such as to be placed in the drift high concentration region 30. According to this structure, it is possible to improve the cosmic ray tolerance in the structure having the trench gate structure 53.

In this case, the trench gate structure 53 is preferably formed in the drift high concentration region 30 at an interval on the first main surface 3 side from the drift gradient region 8. According to this structure, it is possible to suppress a shape change of the drift gradient region 8 following introduction of the trench gate structure 53. That is, it is possible to suppress the electric field distribution in the drift gradient region 8 from being varied due to the trench gate structure 53. Thereby, it is possible to improve the cosmic ray tolerance in the structure having the trench gate structure 53.

Also, according to this structure, it is possible to interpose part of the drift high concentration region 30 in a region between the drift gradient region 8 and the trench gate structure 53. Thereby, it is possible to reduce current spreading resistance along the planar direction of the first main surface 3 by utilizing the drift high concentration region 30 placed immediately below the trench gate structure 53.

The semiconductor device 1B preferably includes the trench source structure 54 formed in the first main surface 3 such as to be placed in the drift high concentration region 30. According to this structure, it is possible to improve the cosmic ray tolerance in the structure having the trench source structure 54. The trench source structure 54 is preferably formed adjacently to the trench gate structure 53.

The trench source structure 54 is preferably formed in the drift high concentration region 30 at an interval on the first main surface 3 side from the drift gradient region 8. According to this structure, it is possible to suppress a shape change of the drift gradient region 8 following introduction of the trench source structure 54. That is, it is possible to suppress the electric field distribution in the drift gradient region 8 from being varied due to the trench source structure 54. Thereby, it is possible to improve the cosmic ray tolerance in the structure having the trench source structure 54.

Also, according to this structure, it is possible to interpose part of the drift high concentration region 30 in a region between the drift gradient region 8 and the trench source structure 54. Thereby, it is possible to reduce the current spreading resistance along the planar direction of the first main surface 3 by utilizing the drift high concentration region 30 placed immediately below the trench source structure 54.

The trench source structure 54 may be formed to be deeper than the trench gate structure 53. The trench source structure 54 may be formed to be shallower than the trench gate structure 53. The trench source structure 54 may be formed to have a substantially equal depth to the trench gate structure 53.

The semiconductor device 1B preferably includes the mesa portion 44 defined in the first main surface 3. The mesa portion 44 is defined in the first main surface 3 by the active surface 41 formed in the inner side portion of the first main surface 3, the outer surface 42 formed in the peripheral edge portion of the first main surface 3 such as to be hollowed toward the second main surface 4 side, and the first to fourth connecting surfaces 43A to 43D that connect the active surface 41 and the outer surface 42.

In such a structure, the active surface 41 is preferably formed by the drift high concentration region 30. Also, the outer surface 42 is preferably formed by the drift high concentration region 30. That is, preferably, the mesa portion 44 is formed only in the drift high concentration region 30 and does not expose the drift gradient region 8.

According to this structure, it is possible to suppress a shape change of the drift gradient region 8 following introduction of the mesa portion 44. That is, it is possible to suppress the electric field distribution in the drift gradient region 8 from being varied due to the mesa portion 44. Thereby, it is possible to improve the cosmic ray tolerance in the structure having the mesa portion 44.

The semiconductor device 1B may include the p-type outer contact region 62 formed in the drift high concentration region 30 in the surface layer portion of the outer surface 42. The semiconductor device 1B may include the p-type outer well region 63 formed in the drift high concentration region 30 in the surface layer portion of the outer surface 42. The outer well region 63 may have a part that covers the first to fourth connecting surfaces 43A to 43D. The semiconductor device 1B may include at least one p-type field regions 64 formed in the drift high concentration region 30 in the surface layer portion of the outer surface 42.

The semiconductor device 1B may include the n-type base region 6 formed in a region on the second main surface 4 side in the chip 2. The semiconductor device 1B may include the buffer region 7 formed in a region on the first main surface 3 side with respect to the base region 6 in the chip 2. In this case, the drift gradient region 8 is preferably formed in a region on the first main surface 3 side with respect to the buffer region 7 in the chip 2.

The buffer region 7 preferably has the impurity concentration lower than the base region 6. The drift gradient region 8 preferably has the impurity concentration lower than the buffer region 7. The drift high concentration region 30 preferably has the impurity concentration lower than the base region 6. The drift high concentration region 30 preferably has the impurity concentration higher than a minimum value of the impurity concentration of the buffer region 7. The drift gradient region 8 is preferably thicker than the buffer region 7.

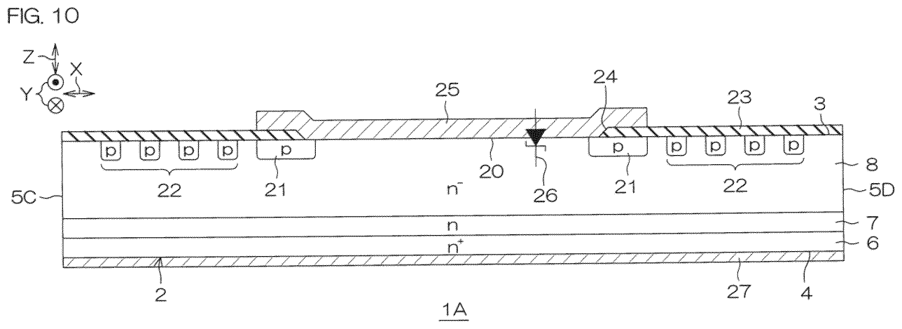

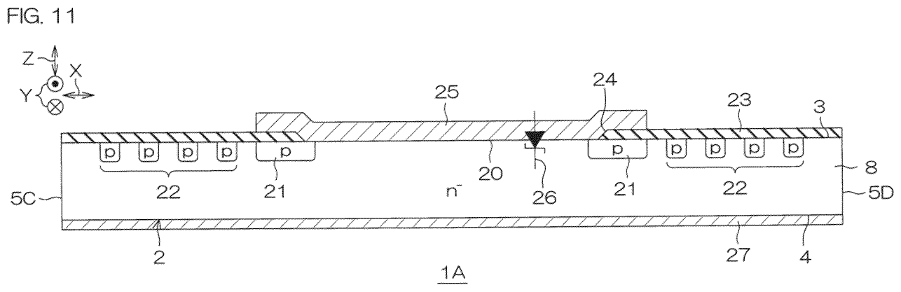

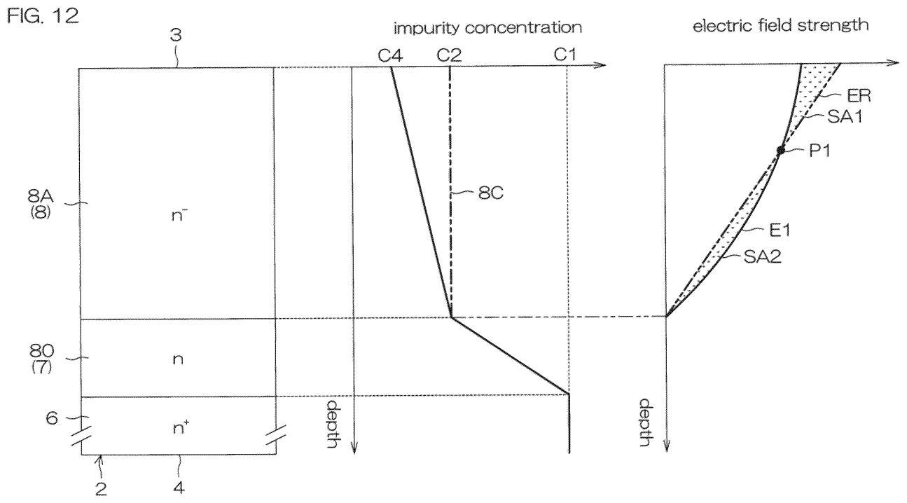

Hereinafter, with reference to FIGS. 10 to 12, modified examples of the chip 2 applied to the embodiments described above will be shown. FIG. 10 is a cross-sectional view corresponding to FIG. 2 and illustrating a first modified example of the chip 2. FIG. 11 is a cross-sectional view corresponding to FIG. 2 and illustrating a second modified example of the chip 2. FIG. 12 is a view corresponding to FIG. 3A and illustrating a third modified example of the chip 2. Although FIGS. 10 to 12 illustrate the embodiment in which chips 2 according to the first to third modified examples are applied to the semiconductor device 1A according to the first embodiment, configurations of the chips 2 according to the first to third modified examples may also be applied to the semiconductor device 1B according to the second embodiment.

With reference to FIG. 10, the chip 2 according to the first modified example includes the base region 6 having the thickness less than the thickness of the drift gradient region 8. In this case, the base region 6 may have the thickness of not less than 0.1 μm and less than 50 μm. The thickness of the base region 6 may be not less than 5 μm (preferably, not less than 10 μm). Such a structure is formed by thinning the chip 2 by grinding, etching, etc., from the second main surface 4 side.

With reference to FIG. 11, the chip 2 according to the second modified example includes only the drift gradient region 8 without having the base region 6 and the buffer region 7. That is, the chip 2 according to the second modified example has a single-layer structure formed by an epitaxial layer without having a semiconductor substrate. The drift gradient region 8 is exposed from the second main surface 4 of the chip 2. Such a structure is formed by thinning the chip 2 by grinding, etching, etc., from the second main surface 4 side.

With reference to FIG. 12, the chip 2 according to the third modified example includes the buffer region 7 having a concentration profile in which an impurity concentration is continuously lowered from the first concentration C1 to the second concentration C2 from the base region 6 toward the first main surface 3 side. That is, the buffer region 7 has a single transition region 80 in which an impurity concentration is continuously lowered from the first concentration C1 to the second concentration C2 without including the first transition region 9, the holding region 10, and the second transition region 11.

It is possible to implement the embodiments described above in further other embodiments. For example, it is possible to appropriately combine the characteristics disclosed in the embodiments described above between the embodiments described above. That is, an embodiment including at least two characteristics among the characteristics disclosed in the first and second embodiments described above at the same time may be adopted.

In the second embodiment described above, the chip 2 having the mesa portion 44 is shown. However, a chip 2 having the first main surface 3 that extends flatly without having the mesa portion 44 may be adopted. In this case, the side wall structure 71 is removed. As a matter of course, in the first embodiment described above, the chip 2 having the mesa portion 44 may also be adopted. In this case, the SBD structure 26 is formed in the active surface 41.

In the second embodiment described above, the embodiment having the source wiring 78 is shown. However, an embodiment having no source wiring 78 may be adopted. In the second embodiment described above, the trench gate structure 53 that controls the channel inside the chip 2 is shown. However, a planar gate structure that controls the channel from above the first main surface 3 may be adopted.

In the embodiments described above, the embodiments in which the SBD structure 26 and the MISFET structure 50 are formed in different chips 2 are shown. However, the SBD structure 26 and the MISFET structure 50 may be formed in different regions of the first main surface 3 in the same chip 2. In this case, the SBD structure 26 may be formed as a reflux diode of the MISFET structure 50. Further, in this case, the source electrode 74 may also serve as the first polar electrode 25 and the drain electrode 79 may also serve as the second polar electrode 27.

In the embodiments described above, the embodiments in which the “first conductivity type” is the “n-type” and the “second conductivity type” is the “p-type” are shown. However, in the embodiments described above, embodiments in which the “first conductivity type” is the “p-type” and the “second conductivity type” is the “n-type” may be adopted. A specific configuration of this case is obtained by replacing the “n-type” with the “p-type” and at the same time replacing the “p-type” with the “n-type” in the description above and the attached drawings.

In the second embodiment described above, the n-type base region 6 is shown. However, a p-type base region 6 may be adopted. In this case, an insulated gate bipolar transistor (IGBT) structure is formed instead of the MISFET structure 50. In this case, in the description above, the “source” of the MISFET structure 50 is replaced with an “emitter” of the IGBT structure, and the “drain” of the MISFET structure 50 is replaced with a “collector” of the IGBT structure. The p-type base region 6 may be an impurity region including a p-type impurity introduced to the surface layer portion of the second main surface 4 of the chip 2 by the ion injecting method.

Characteristic examples extracted from this description and from the drawings are hereinafter shown. Hereinafter, alphanumeric characters etc., in parentheses represent corresponding components in the aforementioned embodiments, and yet this representation does not denote that the scope of each clause is limited to the embodiments. The “semiconductor device” according to the following clauses may be replaced with a “wide-bandgap semiconductor device,” an “SiC semiconductor device,” a “semiconductor switching device,” or a “semiconductor rectifying device,” etc., if necessary.

[A1] A semiconductor device (1A, 1B) comprising: a chip (2) having a first main surface (3) which serves as a device surface and a second main surface (4) which serves as a non-device surface; and a first conductivity type (n-type) drift gradient region (8, 8A, 8B) formed in the chip (2), and having a concentration profile in which an impurity concentration of an end portion on the first main surface (3) side is lower than an impurity concentration of an end portion on the second main surface (4) side.

[A2] The semiconductor device (1A, 1B) according to A1, wherein the drift gradient region (8, 8A, 8B) has the concentration profile in which the impurity concentration is gradually lowered from the second main surface (4) side toward the first main surface (3) side.

[A3] The semiconductor device (1A, 1B) according to A1 or A2, wherein the chip (2) includes a single crystal of a wide-bandgap semiconductor.

[A4] The semiconductor device (1A, 1B) according to A3, wherein the chip (2) includes an SiC single crystal.

[A5] The semiconductor device (1A, 1B) according to any one of A1 to A4, wherein the drift gradient region (8, 8A, 8B) forms an electric field distribution in which an electric field strength is monotonically increased from the second main surface (4) side toward the first main surface (3) side.

[A6] The semiconductor device (1A, 1B) according to any one of A1 to A5, wherein the drift gradient region (8, 8A, 8B) forms an electric field distribution in which an increase ratio of the electric field strength on the first main surface (3) side is smaller than an increase ratio of the electric field strength on the second main surface (4) side.

[A7] The semiconductor device (1A, 1B) according to any one of A1 to A6, wherein the drift gradient region (8, 8A, 8B) has the concentration profile in which the impurity concentration is lowered in a downward inclining manner from the second main surface (4) side toward the first main surface (3) side.

[A8] The semiconductor device (1A, 1B) according to any one of A1 to A6, wherein the drift gradient region (8, 8A, 8B) has the concentration profile in which the impurity concentration is lowered in a downward staircase manner from the second main surface (4) side toward the first main surface (3) side.

[A9] The semiconductor device (1A, 1B) according to any one of A1 to A8, wherein the drift gradient region (8, 8A, 8B) forms the first main surface (3).

[A10] The semiconductor device (1A, 1B) according to A9, further comprising: an electrode (25) arranged on the drift gradient region (8, 8A, 8B) and forms a Schottky junction with the drift gradient region (8, 8A, 8B).

[A11] The semiconductor device (1A, 1B) according to A10, further comprising: a first conductivity type (n-type) diode region (20) formed by utilizing part of the drift gradient region (8, 8A, 8B); and a second conductivity type (p-type) guard region (21) formed along the diode region (20) in a surface layer portion of the first main surface (3); wherein the electrode (25) forms a Schottky junction with the diode region (20) and covers the diode region (20) and the guard region (21) so as to be electrically connected to the guard region (21).

[A12] The semiconductor device (1A, 1B) according to any one of A1 to A8, further comprising: a first conductivity type (n-type) drift high concentration region (30) formed on the first main surface (3) side with respect to the drift gradient region (8, 8A, 8B) in the chip (2), and having an impurity concentration higher than the drift gradient region (8, 8A, 8B).

[A13] The semiconductor device (1A, 1B) according to A12, wherein the drift high concentration region (30) has a thickness less than a thickness of the drift gradient region (8, 8A, 8B).

[A14] The semiconductor device (1A, 1B) according to A12 or A13, further comprising: a trench gate structure (53) formed in the first main surface (3) such as to be placed in the drift high concentration region (30).

[A15] The semiconductor device (1A, 1B) according to A14, wherein the trench gate structure (53) is formed at an interval on the first main surface (3) side from the drift gradient region (8, 8A, 8B).

[A16] The semiconductor device (1A, 1B) according to any one of A12 to A15, further comprising: a trench source structure (54) formed in the first main surface (3) such as to be placed in the drift high concentration region (30).

[A17] The semiconductor device (1A, 1B) according to A16, wherein the trench source structure (54) is formed at an interval on the first main surface (3) side from the drift gradient region (8, 8A, 8B).

[A18] The semiconductor device (1A, 1B) according to any one of A1 to A17, further comprising: a base region (6) formed on the second main surface (4) side in the chip (2); and a buffer region (7) formed on the first main surface (3) side with respect to the base region (6) in the chip (2); wherein the drift gradient region (8, 8A, 8B) is formed on the first main surface (3) side with respect to the buffer region (7) in the chip (2).

[A19] The semiconductor device (1A, 1B) according to A18, wherein the drift gradient region (8, 8A, 8B) is thicker than the buffer region (7).

[A20] The semiconductor device (1A, 1B) according to A18 or A19, further comprising: the first conductivity type (n-type) base region (6); and the first conductivity type (n-type) buffer region (7) having an impurity concentration lower than the base region (6); wherein the drift gradient region (8, 8A, 8B) has an impurity concentration lower than the buffer region (7).

[B1] A semiconductor device (1B) comprising: a chip (2) having a first main surface (3) which serves as a device surface and a second main surface (4) which serves as a non-device surface; a first conductivity type (n-type) drift gradient region (8, 8A, 8B) formed in the chip (2), and having a concentration profile in which an impurity concentration of an end portion on the first main surface (3) side is lower than an impurity concentration of an end portion on the second main surface (4) side; and a first conductivity type (n-type) drift high concentration region (30) formed on the first main surface (3) side with respect to the drift gradient region (8, 8A, 8B) in the chip (2), and having an impurity concentration higher than the drift gradient region (8, 8A, 8B).

[B2] The semiconductor device (1B) according to B1, wherein the chip (2) is formed by a single crystal of a wide-bandgap semiconductor.

[B3] The semiconductor device (1B) according to B1 or B2, wherein the drift gradient region has the concentration profile in which the impurity concentration is gradually lowered from the second main surface (4) side toward the first main surface (3) side.

[B4] The semiconductor device (1B) according to any one of B1 to B3, wherein the drift gradient region (8, 8A, 8B) has the concentration profile in which the impurity concentration is lowered in a downward inclining manner toward the first main surface (3) side.

[B5] The semiconductor device (1B) according to any one of B1 to B3, wherein the drift gradient region (8, 8A, 8B) has the concentration profile in which the impurity concentration is lowered in a downward staircase manner toward the first main surface (3) side.

[B6] The semiconductor device (1B) according to any one of B1 to B5, wherein the drift gradient region (8, 8A, 8B) extends in a layer shape along the first main surface (3), and the drift high concentration region (30) extends in a layer shape along the first main surface (3).

[B7] The semiconductor device (1B) according to any one of B1 to B6, wherein the drift high concentration region (30) forms the first main surface (3).

[B8] The semiconductor device (1B) according to any one of B1 to B7, wherein the drift high concentration region (30) has a thickness less than a thickness of the drift gradient region (8, 8A, 8B).

[B9] The semiconductor device (1B) according to any one of B1 to B8, wherein the drift high concentration region (30) includes a concentration transition region (31) in which the impurity concentration is increased from the drift gradient region (8, 8A, 8B) toward the first main surface (3) side, and a concentration holding region (32) formed to have a fixed impurity concentration from the concentration transition region (31) toward the first main surface (3) side.

[B10] The semiconductor device (1B) according to B9, wherein the concentration holding region (32) is thicker than the concentration transition region (31).

[B11] The semiconductor device (1B) according to any one of B1 to B10, further comprising: a trench gate structure (53) formed in an inner side portion of the first main surface (3) such as to be placed in the drift high concentration region (30).

[B12] The semiconductor device (1B) according to B11, wherein the trench gate structure (53) is formed at an interval on the first main surface (3) side from the drift gradient region (8, 8A, 8B).

[B13] The semiconductor device (1B) according to B11 or B12, further comprising: a trench source structure (54) formed in the inner side portion of the first main surface (3) adjacently to the trench gate structure (53) such as to be placed in the drift high concentration region (30).

[B14] The semiconductor device (1B) according to B13, wherein the trench source structure (54) is deeper than the trench gate structure (53).

[B15] The semiconductor device (1B) according to B13 or B14, wherein the trench source structure (54) is formed at an interval on the first main surface (3) side from the drift gradient region (8, 8A, 8B).

[B16] The semiconductor device (1B) according to any one of B1 to B15, further comprising: a mesa portion (44) defined in the first main surface (3) by a first surface portion (41) formed in the inner side portion of the first main surface (3), a second surface portion (42) formed in a peripheral edge portion of the first main surface (3) such as to be hollowed toward the second main surface (4) side, and connecting surface portions (43A to 43D) that connect the first surface portion (41) and the second surface portion (42).

[B17] The semiconductor device (1B) according to B16, wherein the first surface portion (41) is formed by the drift high concentration region (30), and the second surface portion (42) is formed by the drift high concentration region (30) at an interval from the drift gradient region (8, 8A, 8B).

[B18] The semiconductor device (1B) according to B16 or B17, further comprising: at least one second conductivity type (p-type) field regions (64) formed in the drift high concentration region (30) in a surface layer portion of the second surface portion (42).

[B19] The semiconductor device (1B) according to any one of B1 to B18, further comprising: a base region (6) formed on the second main surface (4) side in the chip (2); and a buffer region (7) formed on the first main surface (3) side with respect to the base region (6) in the chip (2); wherein the drift gradient region (8, 8A, 8B) is formed on the first main surface (3) side with respect to the buffer region (7) in the chip (2).

[B20] The semiconductor device (1B) according to any one of B1 to B19, further comprising: a gate electrode (73) arranged on the first main surface (3); a source electrode (74) arranged on the first main surface (3) at an interval from the gate electrode (73); and a drain electrode (79) arranged on the second main surface (4).

[C1] A semiconductor device (1A, 1B) comprising: a chip (2) having a first main surface (3) which serves as a device surface and a second main surface (4) which serves as a non-device surface; a first conductivity type (n-type) base region (6) formed on the second main surface (4) side in the chip (2); a first conductivity type (n-type) buffer region (7) formed on the first main surface (3) side with respect to the base region (6) in the chip (2), and having an impurity concentration lower than the base region (6); and a first conductivity type (n-type) drift gradient region (8, 8A, 8B) formed on the first main surface (3) side with respect to the buffer region (7) in the chip (2), having an impurity concentration lower than the buffer region (7), and having a concentration profile in which an impurity concentration on the first main surface (3) side is lower than an impurity concentration on the buffer region (7) side.

[C2] The semiconductor device (1A, 1B) according to C1, wherein the drift gradient region (8, 8A, 8B) has the concentration profile in which the impurity concentration is gradually lowered from the buffer region (7) side toward the first main surface (3) side.

[C3] The semiconductor device (1A, 1B) according to C1 or C2, wherein the drift gradient region (8, 8A, 8B) forms an electric field distribution in which an electric field strength is monotonically increased from the buffer region (7) side toward the first main surface (3) side.

[C4] The semiconductor device (1A, 1B) according to any one of C1 to C3, wherein the drift gradient region (8, 8A, 8B) forms an electric field distribution in which an increase ratio of the electric field strength on the first main surface (3) side is smaller than an increase ratio of the electric field strength on the buffer region (7) side.

Although the embodiments have been described in detail as above, these are merely concrete examples that specify technical contents. Various technical ideas extracted from this description can be appropriately combined together without being limited to the sequential descriptive order in this description, the sequential order of the embodiments, or the like.

What is claimed is:

1. A semiconductor device comprising:
a chip having a first main surface which serves as a device surface and a second main surface which serves as a non-device surface; and
a first conductivity type drift gradient region formed in the chip, and having a concentration profile in which an impurity concentration of an end portion on the first main surface side is lower than an impurity concentration of an end portion on the second main surface side.

2. The semiconductor device according to claim 1,
wherein the drift gradient region has the concentration profile in which the impurity concentration is gradually lowered from the second main surface side toward the first main surface side.

3. The semiconductor device according to claim 1,
wherein the chip includes a single crystal of a wide-bandgap semiconductor.

4. The semiconductor device according to claim 3,
wherein the chip includes an SiC single crystal.

5. The semiconductor device according to claim 1,
wherein the drift gradient region forms an electric field distribution in which an electric field strength is monotonically increased from the second main surface side toward the first main surface side.

6. The semiconductor device according to claim 1,
wherein the drift gradient region forms an electric field distribution in which an increase ratio of the electric field strength on the first main surface side is smaller than an increase ratio of the electric field strength on the second main surface side.

7. The semiconductor device according to claim 1,
wherein the drift gradient region has the concentration profile in which the impurity concentration is lowered in a downward inclining manner from the second main surface side toward the first main surface side.

8. The semiconductor device according to claim 1,
wherein the drift gradient region has the concentration profile in which the impurity concentration is lowered in a downward staircase manner from the second main surface side toward the first main surface side.

9. The semiconductor device according to claim 1,
wherein the drift gradient region forms the first main surface.

10. The semiconductor device according to claim 9, further comprising:
an electrode arranged on the drift gradient region and forms a Schottky junction with the drift gradient region.

11. The semiconductor device according to claim 10, further comprising:
a first conductivity type diode region formed by utilizing part of the drift gradient region; and
a second conductivity type guard region formed along the diode region in a surface layer portion of the first main surface;
wherein the electrode forms a Schottky junction with the diode region and covers the diode region and the guard region so as to be electrically connected to the guard region.

12. The semiconductor device according to claim 1, further comprising:
a first conductivity type drift high concentration region formed on the first main surface side with respect to the drift gradient region in the chip, and having an impurity concentration higher than the drift gradient region.

13. The semiconductor device according to claim 12,
wherein the drift high concentration region has a thickness less than a thickness of the drift gradient region.

14. The semiconductor device according to claim 12 further comprising:
a trench gate structure formed in the first main surface such as to be placed in the drift high concentration region.

15. The semiconductor device according to claim 14,
wherein the trench gate structure is formed at an interval on the first main surface side from the drift gradient region.

16. The semiconductor device according to claim 12, further comprising:
a trench source structure formed in the first main surface such as to be placed in the drift high concentration region.

17. The semiconductor device according to claim 16,
wherein the trench source structure is formed at an interval on the first main surface side from the drift gradient region.

18. The semiconductor device according to claim 1, further comprising:
a base region formed on the second main surface side in the chip; and
a buffer region formed on the first main surface side with respect to the base region in the chip;
wherein the drift gradient region is formed on the first main surface side with respect to the buffer region in the chip.

19. The semiconductor device according to claim 18,
wherein the drift gradient region is thicker than the buffer region.

20. The semiconductor device according to claim 18, further comprising:
the first conductivity type base region; and
the first conductivity type buffer region having an impurity concentration lower than the base region,
wherein the drift gradient region has an impurity concentration lower than the buffer region.
